(19) United States
(12) Patent Application Publication
(10) Pub. No.: US 2026/0156927 A1
(43) Pub. Date: Jun. 4, 2026

(54) INTEGRATED CIRCUIT DEVICE

(71) Applicant: Samsung Electronics Co., Ltd., Suwon-si (KR)

(72) Inventors: Jieun Han, Suwon-si (KR); Jeongyeon Seo, Suwon-si (KR); Kwangyong Yang, Suwon-si (KR); Sangeun Yun, Suwon-si (KR); Wonhyuk Lee, Suwon-si (KR)

(21) Appl. No.: 19/285,480

(22) Filed: Jul. 30, 2025

(30) Foreign Application Priority Data
Dec. 4, 2024 (KR) 10-2024-0178886

(51) Int. Cl. H10D 84/83; H01L 23/522; H01L 23/528; H10D 30/00; H10D 30/01; H10D 30/43; H10D 62/10; H10D 62/13; H10D 64/23; H10D 84/01

(52) U.S. Cl. CPC H10D 84/832; H10D 30/43; H10D 30/502; H10D 62/121; H10D 62/151; H10D 64/256; H10D 84/8312; H10D 84/83125; H10W 20/42; H10W 20/435; H10D 30/014; H10D 30/0191; H10D 84/0149

(57) ABSTRACT

An example of an integrated circuit device includes a channel region, a gate line surrounding the channel region and having a first upper surface at a first level that is apart from a reference level of an uppermost surface of the channel region in a vertical direction, a source/drain contact connected to the source/drain region and having a second upper surface at the first level, a gate contact arranged at a second level higher than the first level and connected to the gate line, a source/drain via contact at the second level and connected to the source/drain contact, and a metal-containing conductive liner between the first and second levels, contacting one of the first upper surface of the gate line and the second upper surface of the source/drain contact, and having a width greater than the width of the selected one.

### CROSS-REFERENCE TO RELATED APPLICATION

This application is based on and claims priority under 35 U.S.C. § 119 to Korean Patent Application No. 10-2024-0178886, filed on Dec. 4, 2024, in the Korean Intellectual Property Office, the disclosure of which is incorporated by reference herein in its entirety.

### BACKGROUND

Along with the rapid down-scaling of integrated circuit devices, it may be desired for integrated circuit devices to secure high operation speeds and the accuracy in operations as well. Therefore, research has been conducted to provide integrated circuit devices that have structures capable of providing optimum performance and improving the reliability thereof.

### SUMMARY

The present disclosure provides an integrated circuit device having a structure allowing the reliability of the integrated circuit device to be secured and a fabrication process of the integrated circuit device to be simplified, when the integrated circuit device includes a plurality of wiring structures arranged in a reduced area due to down-scaling.

According to an aspect of the present disclosure, an integrated circuit device includes a channel region, a gate line surrounding the channel region and having a first upper surface that extends at a first vertical level, the first vertical level being apart from a reference vertical level of an uppermost surface of the channel region in a vertical direction, a source/drain region contacting the channel region, a source/drain contact arranged over the source/drain region so as to be connected to the source/drain region and having a second upper surface that extends at the first vertical level, a gate contact arranged at a second vertical level and configured to be connected to the gate line, the second vertical level being higher than the first vertical level, a source/drain via contact arranged at the second vertical level and configured to be connected to the source/drain contact, and a metal-containing conductive liner arranged between the first vertical level and the second vertical level and contacting one selected from the first upper surface of the gate line and the second upper surface of the source/drain contact, the metal-containing conductive liner having a width that is greater in a first horizontal direction than a width of the selected one.

According to another aspect of the present disclosure, an integrated circuit device includes a plurality of channel regions apart from each other in a first horizontal direction, a plurality of gate lines respectively surrounding the plurality of channel regions and each extending lengthwise in a second horizontal direction that is perpendicular to the first horizontal direction, each of the plurality of gate lines having a first upper surface extending at a first vertical level that is apart from a reference vertical level of an uppermost surface of each of the plurality of channel regions in a vertical direction, a plurality of source/drain regions arranged one-by-one between two adjacent gate lines from among the plurality of gate lines, a plurality of source/drain contacts each configured to be connected to a source/drain region selected from the plurality of source/drain regions, each of the plurality of source/drain contacts having a second upper surface extending at the first vertical level, a plurality of gate contacts arranged at a second vertical level and each configured to be connected to a gate line selected from the plurality of gate lines, the second vertical level being higher than the first vertical level, a plurality of source/drain via contacts arranged at the second vertical level and each configured to be connected to a source/drain contact selected from the plurality of source/drain contacts, a plurality of insulating spacers arranged one-by-one between each of the plurality of gate lines and each of the plurality of source/drain contacts, and a first metal-containing conductive liner including a portion in contact with the first upper surface of a first gate line, which is selected from the plurality of gate lines, and a portion covering an upper surface of a first insulating spacer, which is selected from the plurality of insulating spacers and adjacent to the first upper surface of the first gate line, the first metal-containing conductive liner having a width that is greater in the first horizontal direction than a width of the first upper surface of the first gate line, wherein a first gate contact selected from the plurality of gate contacts is apart from the first gate line in the vertical direction with the first metal-containing conductive liner therebetween and connected to the first gate line via the first metal-containing conductive liner.

According to another aspect of the present disclosure, an integrated circuit device includes a plurality of nanosheet stacks each including a plurality of nanosheets overlapping each other in a vertical direction, a plurality of gate lines, which each surround the plurality of nanosheets of a nanosheet stack selected from the plurality of nanosheet stacks and each have a first upper surface extending at a first vertical level, the first vertical level being apart from a reference vertical level of an uppermost surface of the selected nanosheet stack in the vertical direction, a plurality of source/drain regions arranged one-by-one between two adjacent gate lines from among the plurality of gate lines, a plurality of source/drain contacts each configured to be connected to a source/drain region selected from the plurality of source/drain regions, each of the plurality of source/drain contacts having a second upper surface extending at the first vertical level, a plurality of gate contacts arranged at a second vertical level and each configured to be connected to a gate line selected from the plurality of gate lines, the second vertical level being higher than the first vertical level, a plurality of source/drain via contacts arranged at the second vertical level and each configured to be connected to a source/drain contact selected from the plurality of source/drain contacts, a plurality of insulating spacers arranged one-by-one between each of the plurality of gate lines and each of the plurality of source/drain contacts, a first metal-containing conductive liner including a portion in contact with the first upper surface of a first gate line, which is selected from the plurality of gate lines, and a portion covering an upper surface of a first insulating spacer, which is selected from the plurality of insulating spacers and adjacent to the first upper surface of the first gate line, the first metal-containing conductive liner having a width that is greater in the first horizontal direction than a width of the first upper surface of the first gate line, and a second metal-containing conductive liner including a portion in contact with the second upper surface of a first source/drain contact, which is selected from the plurality of source/drain contacts, and a portion covering an upper surface of a second insulating spacer, which is selected from the plurality of insulating spacers and adjacent to the second upper surface of the first source/drain contact, the second metal-containing conductive liner having a width that is greater in the first horizontal direction than a width of the second upper surface of the first source/drain contact.

### BRIEF DESCRIPTION OF THE DRAWINGS

Implementations will be more clearly understood from the following detailed description taken in conjunction with the accompanying drawings in which:

FIG. 1 is a schematic plan view of an example of a cell block of an integrated circuit device, according to implementations;

FIG. 2 is a planar layout diagram illustrating an integrated circuit device according to implementations;

FIG. 3A is a cross-sectional view illustrating cross-sectional configurations of the integrated circuit device of FIG. 2, respectively taken along a line X1-X1′ of FIG. 2 and a line X2-X2′ of FIG. 2;

FIG. 3B is a cross-sectional view of the integrated circuit device of FIG. 2, taken along a line Y1-Y1′ of FIG. 2;

FIG. 3C is a cross-sectional view of the integrated circuit device of FIG. 2, taken along a line Y2-Y2′ of FIG. 2;

FIG. 3D is an enlarged cross-sectional view of a region EX1 of FIG. 3A;

FIG. 3E is an enlarged cross-sectional view of a region EX2 of FIG. 3A;

FIGS. 4A and 4B are cross-sectional views illustrating an integrated circuit device according to some implementations;

FIG. 5 is a cross-sectional view illustrating an integrated circuit device according to some implementations;

FIG. 6 is a cross-sectional view illustrating an integrated circuit device according to some implementations;

FIGS. 7A and 7B are cross-sectional views illustrating an integrated circuit device according to some implementations;

FIG. 8 is a cross-sectional view illustrating an integrated circuit device according to some implementations;

FIG. 9 is a cross-sectional view illustrating an integrated circuit device according to some implementations;

FIG. 10 is a block diagram of an integrated circuit device according to implementations;

FIGS. 11A to 29 are diagrams respectively illustrating a sequence of processes of a method of fabricating an integrated circuit device, according to some implementations;

FIGS. 30 to 33 are diagrams respectively illustrating a sequence of processes of a method of fabricating an integrated circuit device, according to some implementations; and

FIGS. 34A to 40 are diagrams respectively illustrating a sequence of processes of a method of fabricating an integrated circuit device, according to some implementations.

### DETAILED DESCRIPTION

Hereinafter, implementations of the present disclosure will be described in detail with reference to the accompanying drawings. Like components are denoted by like reference numerals throughout the specification, and repeated descriptions thereof are omitted.

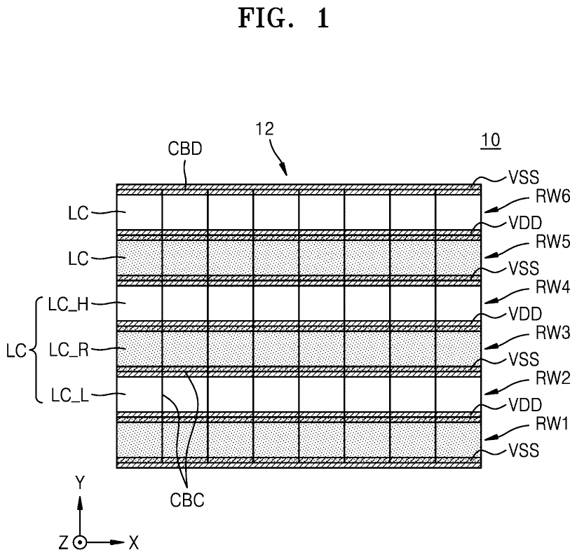

FIG. 1 is a schematic plan view of an example of a cell block 12 of an integrated circuit device 10 according to implementations.

Referring to FIG. 1, the cell block 12 of the integrated circuit device 10 may include a plurality of cells LC including circuit patterns for constituting various circuits. The plurality of cells LC may be arranged in a matrix in a width direction (an X direction in FIG. 1) and a height direction (a Y direction in FIG. 1) in the cell block 12.

The plurality of cells LC may include a circuit pattern having a layout designed by a Place and Route (PnR) technique to perform at least one logical function. The plurality of cells LC may perform various logical functions. In some implementations, the plurality of cells LC may include a plurality of standard cells. In some implementations, at least some of the plurality of cells LC may perform the same logical function. In some implementations, at least some of the plurality of cells LC may respectively perform different logical functions.

The plurality of cells LC may include various types of logic cells including a plurality of circuit elements. For example, each of the plurality of cells LC may include, but is not limited to, an AND, a NAND, an OR, a NOR, an exclusive OR (XOR), an exclusive NOR (XNOR), an inverter (INV), an adder (ADD), a buffer (BUF), a delay (DLY), a filter (FIL), a multiplexer (MXT/MXIT), an OR/AND/INVERTER (OAI), an AND/OR (AO), an AND/OR/INVERTER (AOI), a D flip-flop, a reset flip-flop, a master-slave flip-flop, a latch, or any combination thereof.

In the cell block 12, at least some of the plurality of cells LC constituting one row (that is, RW1, RW2, RW3, RW4, RW5, or RW6) in the width direction (the X direction in FIG. 1) may have the same width. In addition, at least some of the plurality of cells LC constituting one row (that is, RW1, RW2, RW3, RW4, RW5, or RW6) may each have the same height. However, the present disclosure is not limited to the example shown in FIG. 1, and at least some of the plurality of cells LC constituting one row (that is, RW1, RW2, RW3, RW4, RW5, or RW6) may have different widths and heights from each other.

The area of each of the plurality of cells LC in the cell block 12 of the integrated circuit device 10 may be defined by a cell boundary CBD. A cell interface portion CBC, at which respective cell boundaries CBD meet each other, may be arranged between two adjacent cells LC in the width direction (the X direction in FIG. 1) or the height direction (the Y direction in FIG. 1) from among the plurality of cells LC.

In some implementations, two adjacent cells LC in the width direction, among the plurality of cells LC constituting one row (that is, RW1, RW2, RW3, RW4, RW5, or RW6), may be in contact with each other at the cell interface portion CBC without a separation distance therebetween. In some implementations, two adjacent cells LC in the width direction, among the plurality of cells LC constituting one row (that is, RW1, RW2, RW3, RW4, RW5, or RW6), may be apart from each other with a certain separation distance therebetween.

In some implementations, in the plurality of cells LC constituting one row (that is, RW1, RW2, RW3, RW4, RW5, or RW6), two adjacent cells LC may perform the same function. In this case, the two adjacent cells LC may have the same structure. In some implementations, in the plurality of cells LC constituting one row (that is, RW1, RW2, RW3, RW4, RW5, or RW6), two adjacent cells LC may respectively perform different functions.

In some implementations, one cell LC selected from the plurality of cells LC, which are included in the cell block 12 of the integrated circuit device 10, and another cell LC adjacent to the selected cell LC in the height direction (the Y direction in FIG. 1) may have symmetric structures to each other about the cell interface portion CBC therebetween. For example, a reference logic cell LC_R in the third row RW3 and a lower logic cell LC_L in the second row RW2 may have symmetric structures to each other about the cell interface portion CBC therebetween. In addition, the reference logic cell LC_R in the third row RW3 and an upper logic cell LC_H in the fourth row RW4 may have symmetric structures to each other about the cell interface portion CBC therebetween. Although FIG. 1 illustrates the cell block 12 including six rows (that is, RW1, RW2, RW3, RW4, RW5, and RW6), this is only an example. The cell block 12 may include rows in various numbers selected as needed, and one row may include logic cells in various numbers selected as needed.

One selected from among a plurality of ground lines VSS and a plurality of power lines VDD may be arranged between a plurality of rows (that is, RW1, RW2, RW3, RW4, RW5, and RW6), which each include the plurality of cells LC arranged in a line in the width direction (the X direction in FIG. 1). The plurality of ground lines VSS and the plurality of power lines VDD may each extend in a first horizontal direction (the X direction) and may be alternately arranged apart from each other in a second horizontal direction (the Y direction). The second horizontal direction (the Y direction) is a direction orthogonal to the first horizontal direction (the X direction). Therefore, each of the plurality of ground lines VSS and the plurality of power lines VDD may be arranged to overlap the cell boundary CBD of the cell LC, the cell boundary CBD extending in the second horizontal direction (the Y direction).

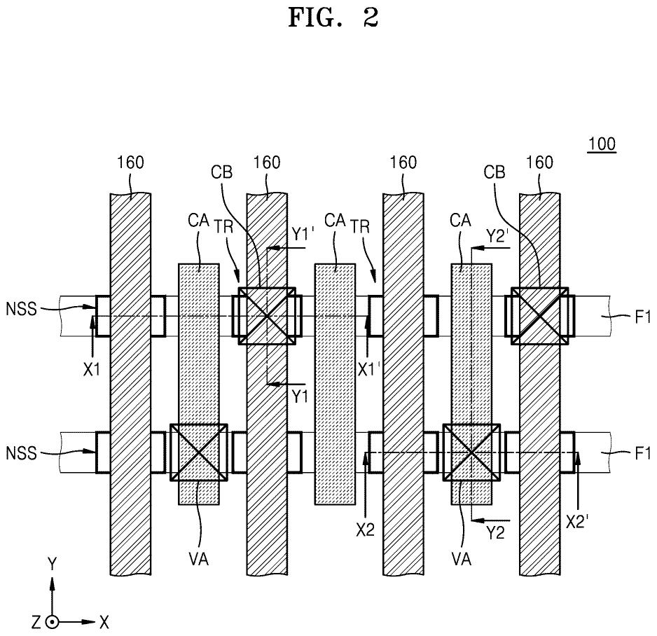

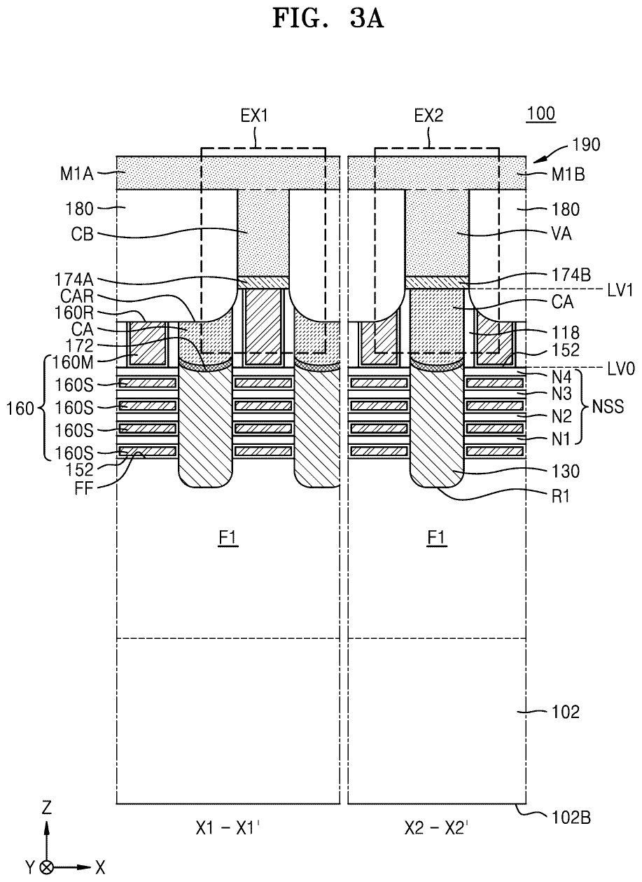

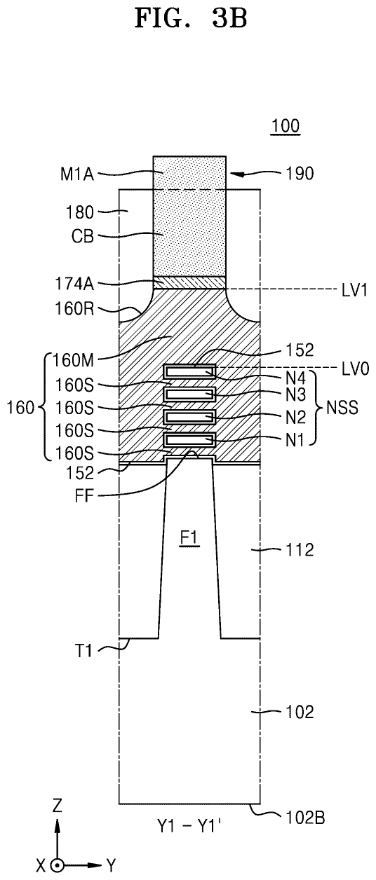

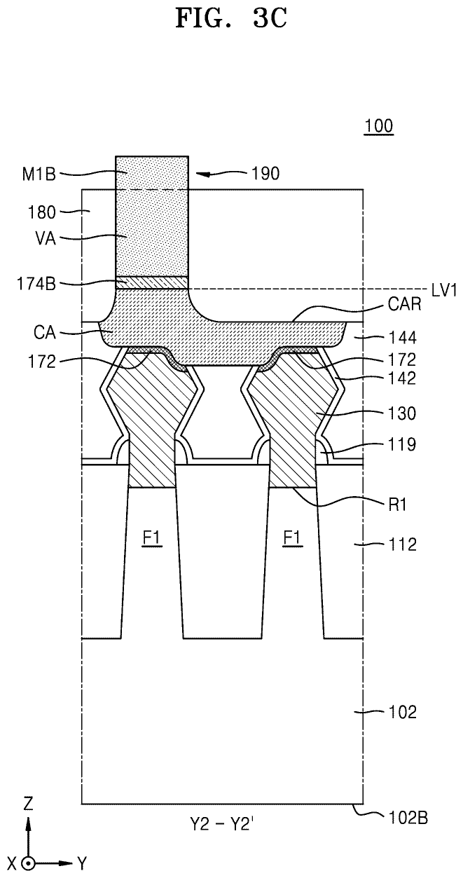

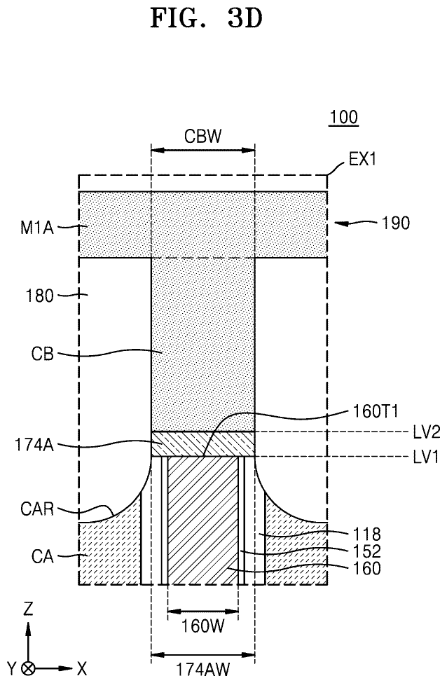

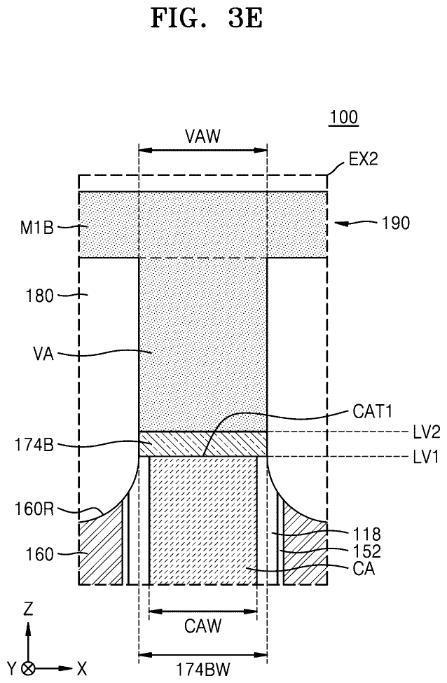

FIG. 2 is a planar layout diagram illustrating an integrated circuit device 100 according to implementations. FIG. 3A is a cross-sectional view illustrating cross-sectional configurations of the integrated circuit device 100, respectively taken along a line X1-X1′ of FIG. 2 and a line X2-X2′ of FIG. 2. FIG. 3B is a cross-sectional view of the integrated circuit device 100, taken along a line Y1-Y1′ of FIG. 2. FIG. 3C is a cross-sectional view of the integrated circuit device 100, taken along a line Y2-Y2′ of FIG. 2. FIG. 3D is an enlarged cross-sectional view of a region EX1 of FIG. 3A. FIG. 3E is an enlarged cross-sectional view of a region EX2 of FIG. 3A. The integrated circuit device 100 including a field-effect transistor TR, which has a gate-all-around structure including a nanowire or nanosheet-shaped channel region and a gate surrounding the channel region, is described with reference to FIGS. 2 and 3A to 3E. The components shown in FIGS. 2 and 3A to 3E, in the integrated circuit device 100, may constitute a portion of the plurality of cells LC shown in FIG. 1.

Referring to FIGS. 2 and 3A to 3E, the integrated circuit device 100 may include a plurality of fin-type active regions F1 protruding from a substrate 102 and extending lengthwise in the first horizontal direction (the X direction), a plurality of nanosheet stacks NSS arranged upwardly apart from each of the plurality of fin-type active regions F1 in a vertical direction (a Z direction) and each facing a fin top surface FF of a fin-type active region F1, a plurality of gate lines 160 each surrounding the plurality of nanosheet stacks NSS, and a plurality of source/drain regions 130 arranged one-by-one between two adjacent gate lines 160 from among the plurality of gate lines 160.

The plurality of fin-type active regions F1 may be apart from each other in the second horizontal direction (the Y direction). Each of the plurality of gate lines 160 may be surrounded by a gate dielectric film 152. The plurality of gate lines 160, the plurality of nanosheet stacks NSS, and the plurality of source/drain regions 130 may constitute a plurality of field-effect transistors TR.

The substrate 102 may include a semiconductor, such as Si or Ge, or a compound semiconductor, such as SiGe, SiC, GaAs, InAs, InGaAs, or InP. As used herein, each of the terms “SiGe”, “SiC”, “GaAs”, “InAs”, “InGaAs”, and “InP” refers to a material including elements contained in each term and is not a chemical formula representing a stoichiometric relationship. The substrate 102 may include a conductive region, for example, an impurity-doped well or an impurity-doped structure.

A trench T1 may be formed in the substrate 102 to define the fin-type active region F1. The trench T1 may be filled with a device isolation film 112. The device isolation film 112 may include a silicon oxide film. The plurality of gate lines 160 may be arranged over the plurality of fin-type active regions F1 and a plurality of device isolation films 112. Each of the plurality of gate lines 160 may extend lengthwise in the second horizontal direction (the Y direction) that is perpendicular to the first horizontal direction (the X direction). In intersection regions between each fin-type active regions F1 and the plurality of gate lines 160, each of the plurality of nanosheet stacks NSS may be arranged over the fin top surface FF of each fin-type active region F1.

Each of the plurality of nanosheet stacks NSS may include at least one nanosheet. As shown in FIGS. 3A and 3B, each of the plurality of nanosheet stacks NSS may include first to fourth nanosheets N1, N2, N3, and N4 overlapping each other in the vertical direction (the Z direction) over the fin-type active region F1. Each of the first to fourth nanosheets N1, N2, N3, and N4 of a nanosheet stack NSS may provide a channel region. As used herein, the term “nanosheet” refers to a conductive structure having a cross-section that is substantially perpendicular to a current-flowing direction. The nanosheet may also be understood as including a nanowire. Herein, the first to fourth nanosheets N1, N2, N3, and N4 and the nanosheet stack NSS including the first to fourth nanosheets N1, N2, N3, and N4 may each be referred to as a channel region.

In some implementations, each of the first to fourth nanosheets N1, N2, N3, and N4 of the nanosheet stack NSS may include a Si layer, a SiGe layer, or a combination thereof. For example, each of the first to fourth nanosheets N1, N2, N3, and N4 may include a Si layer.

The first to fourth nanosheets N1, N2, N3, and N4 may respectively have different vertical distances (Z-direction distances) from the fin top surface FF of the fin-type active region F1. Each of the plurality of gate lines 160 may surround the first to fourth nanosheets N1, N2, N3, and N4, which overlap each other in the vertical direction (the Z direction) and are included in the nanosheet stack NSS.

Although FIG. 2 illustrates an example in which the nanosheet stack NSS has a planar shape that may approximate a quadrangle, the present disclosure is not limited thereto. The nanosheet stack NSS may have various planar shapes depending on the planar shape of each of the fin-type active region F1 and the gate line 160. The plurality of nanosheet stacks NSS may be apart from each other in the first horizontal direction (the X direction) over one fin-type active region F1. The present example illustrates a configuration, in which a plurality of nanosheet stacks NSS and a plurality of gate lines 160 are arranged over one fin-type active region F1 and the plurality of nanosheet stacks NSS are arranged in a line in the first horizontal direction (the X direction) over the one fin-type active region F1. However, the respective numbers of nanosheet stacks NSS and gate lines 160, which are arranged over one fin-type active region F1, are not particularly limited and may be variously modified as needed. Although FIGS. 3A and 3B illustrate an example in which each of the plurality of nanosheet stacks NSS includes four nanosheets including the first to fourth nanosheets N1, N2, N3, and N4, the present disclosure is not limited thereto. For example, the nanosheet stack NSS may include at least one nanosheet, and the number of nanosheets constituting the nanosheet stack NSS is not particularly limited.

In some implementations, each of the first to fourth nanosheets N1, N2, N3, and N4 may have, but is not limited to, a thickness selected from a range of about 4 nm to about 6 nm. Here, the thickness of each of the first to fourth nanosheets N1, N2, N3, and N4 refers to a size in the vertical direction (the Z direction). In some implementations, the first to fourth nanosheets N1, N2, N3, and N4 may have substantially the same thickness in the vertical direction (the Z direction). In some implementations, at least some of the first to fourth nanosheets N1, N2, N3, and N4 may respectively have different thicknesses in the vertical direction (the Z direction).

As shown in FIG. 3A, the first to fourth nanosheets N1, N2, N3, and N4, which are included in one nanosheet stack NSS, may have equal or similar sizes to each other in the first horizontal direction (the X direction). In some implementations, unlike the example shown in FIG. 3A, at least some of the first to fourth nanosheets N1, N2, N3, and N4, which are included in one nanosheet stack NSS, may respectively have different sizes in the first horizontal direction (the X direction).

As shown in FIGS. 3A and 3B, each of the plurality of gate lines 160 may include a main gate portion 160M and a plurality of sub-gate portions 160S. The main gate portion 160M may extend lengthwise in the second horizontal direction (the Y direction) to cover the upper surface of the nanosheet stack NSS. The plurality of sub-gate portions 160S may be integrally connected to the main gate portion 160M and may be respectively arranged one-by-one between the first to fourth nanosheets N1, N2, N3, and N4 and between the first nanosheet N1 and the fin top surface FF of the fin-type active region F1. In the vertical direction (the Z direction), the thickness of each of the plurality of sub-gate portions 160S may be less than the thickness of the main gate portion 160M.

Each of the plurality of gate lines 160 may include a metal, a metal nitride, a metal carbide, or any combination thereof. The metal may be selected from Mo, Ru, Cu, and W. The metal nitride may be selected from TiN, TaN, TiAlN, and any combination thereof. The metal carbide may include TiAlC. However, a material constituting each of the plurality of gate lines 160 is not limited to the examples set forth above.

As shown in FIG. 3B, the device isolation film 112 may be arranged between the substrate 102 and the gate line 160 in the vertical direction (the Z direction). The device isolation film 112 may cover a sidewall of each of the plurality of fin-type active regions F1 in the second horizontal direction (the Y direction).

As shown in FIGS. 3A and 3C, a plurality of recesses R1 may be formed in the fin-type active region F1. A vertical level of the lowermost surface of each of the plurality of recesses R1 may be lower than a vertical level of the fin top surface FF of the fin-type active region F1. The plurality of source/drain regions 130 may be respectively arranged in the plurality of recesses R1. Each of the plurality of source/drain regions 130 may be arranged adjacent to at least one gate line 160 selected from the plurality of gate lines 160. The plurality of source/drain regions 130 on one fin-type active region F1 may be arranged one-by-one between two adjacent gate lines 160 from among the plurality of gate lines 160.

Each of the plurality of source/drain regions 130 may have surfaces contacting the first to fourth nanosheets N1, N2, N3, and N4 that are included in the nanosheet stack NSS adjacent thereto.

Each of the plurality of source/drain regions 130 may include an epitaxially grown semiconductor layer. In some implementations, each of the plurality of source/drain regions 130 may include an epitaxially grown Si layer, an epitaxially grown SiC layer, or a plurality of SiGe layers that are epitaxially grown. When the source/drain region 130 constitutes an NMOS transistor, the source/drain region 130 may include a Si layer doped with an n-type dopant or a SiC layer doped with an n-type dopant. The n-type dopant may be selected from phosphorus (P), arsenic (As), and antimony (Sb). When the source/drain region 130 constitutes a PMOS transistor, the source/drain region 130 may include a SiGe layer doped with a p-type dopant. The p-type dopant may be selected from boron (B) and gallium (Ga).

As shown in FIGS. 3A, 3B, and 3D, each of the plurality of gate lines 160 may have a first upper surface 160T1 extending flat in a horizontal direction, for example, the first horizontal direction (the X direction) and the second horizontal direction (the Y direction), at a first vertical level LV1 that is apart from a reference vertical level LV0 by as much as a first distance in the vertical direction (the Z direction), the reference vertical level LV0 being a vertical level of the uppermost surface of the nanosheet stack NSS. The first distance is the shortest distance between the reference vertical level LV0 and the first vertical level LV1. The uppermost surface, which is defined as the reference vertical level LV0, of the nanosheet stack NSS may correspond to the upper surface of the fourth nanosheet N4. Portions of the upper surface, which are around the first upper surface 160T1, of each of the plurality of gate lines 160 may include a gate recess surface 160R extending at a vertical level that is lower than that of the first upper surface 160T1.

As shown in FIG. 3A, both sidewalls of each of the plurality of gate lines 160 in the first horizontal direction (the X direction) may each be covered by an insulating spacer 118. A plurality of insulating spacers 118 of the integrated circuit device 100 may each be arranged on the nanosheet stack NSS and the device isolation film 112 to extend lengthwise in the second horizontal direction (the Y direction) together with the gate line 160. The insulating spacer 118 may be arranged on the upper surface of each of the plurality of nanosheet stacks NSS to cover either sidewall of the main gate portion 160M. The insulating spacer 118 may be apart from the gate line 160 with the gate dielectric film 152 therebetween. The insulating spacer 118 may include silicon nitride, silicon oxide, SiCN, SiBN, SiON, SiOCN, SiBCN, SiOC, or any combination thereof. As used herein, each of the terms “SiCN”, “SiBN”, “SiON”, “SiOCN”, “SiBCN”, and “SiOC” refers to a material including elements contained in each term and is not a chemical formula representing a stoichiometric relationship.

The gate dielectric film 152 may be arranged between the nanosheet stack NSS and the gate line 160. The gate dielectric film 152 may include a stack structure of an interface dielectric film and a high-k film. The interface dielectric film may include a low-k material film having a dielectric constant of about 9 or less, for example, a silicon oxide film, a silicon oxynitride film, or any combination thereof. In some implementations, the interface dielectric film may be omitted. The high-k film may include a material having a dielectric constant that is greater than that of a silicon oxide film. For example, the high-k film may have a dielectric constant of about 10 to about 25. The high-k film may include, but is not limited to, hafnium oxide.

Both sidewalls of each of the plurality of sub-gate portions 160S, which are included in each of the plurality of gate lines 160, may each be apart from the source/drain region 130 with the gate dielectric film 152 therebetween. The gate dielectric film 152 may include portions between each sub-gate portion 160S of the gate line 160 and each of the first to fourth nanosheets N1, N2, N3, and N4, portions between each sub-gate portion 160S of the gate line 160 and the source/drain region 130, and a portion between the fin top surface FF of the fin-type active region F1 and the sub-gate portion 160S closest to the fin top surface FF from among the plurality of sub-gate portions 160S of the gate line 160.

As shown in FIGS. 3A and 3C, a metal silicide film 172 may be arranged on the upper surface of each of the plurality of source/drain regions 130. The metal silicide film 172 may include a metal including Ti, W, Ru, Nb, Mo, Hf, Ni, Co, Pt, Yb, Tb, Dy, Er, or Pd. For example, the metal silicide film 172 may include, but is not limited to, titanium silicide.

As shown in FIG. 3C, an insulating liner 142 and an inter-gate dielectric 144 may be arranged in the stated order on the plurality of source/drain regions 130. The insulating liner 142 and the inter-gate dielectric 144 may constitute an inter-gate insulating structure. The plurality of source/drain regions 130 may be covered by the insulating liner 142. In some implementations, the insulating liner 142 may include, but is not limited to, silicon nitride (SiN), SiCN, SiBN, SiON, SiOCN, SiBCN, or any combination thereof. The inter-gate dielectric 144 may include, but is not limited to, a silicon oxide film.

The device isolation film 112 may have an upper surface contacting the insulating liner 142. A plurality of side insulating spacers 119 may be respectively arranged on the device isolation film 112 on both sides of the sour/drain region 130 in the second horizontal direction (the Y direction). Each of the plurality of side insulating spacers 119 may cover a sidewall of a portion, which is adjacent to the fin-type active region F1, of the source/drain region 130. The plurality of side insulating spacers 119 may be covered by the insulating liner 142. Each of the plurality of side insulating spacers 119 may include the same material as the constituent material of the insulating spacer 118. In some implementations, at least some of the plurality of side insulating spacers 119 may be omitted.

As shown in FIGS. 3A and 3C, a plurality of source/drain contacts CA may be respectively arranged over the plurality of source/drain regions 130. Each of the plurality of source/drain contacts CA may pass through the inter-gate insulating structure including the inter-gate dielectric 144 and the insulating liner 142 in the vertical direction (the Z direction) and may be configured to be electrically connected to at least one source/drain region 130 selected from the plurality of source/drain regions 130. A portion of the lower surface of each of the plurality of source/drain contacts CA may be in contact with the metal silicide film 172 on the source/drain region 130. The metal silicide film 172 may be arranged between the source/drain region 130 and the source/drain contact CA.

Each of the plurality of source/drain contacts CA may be configured to be electrically connected to the source/drain region 130 via the metal silicide film 172. Each of the plurality of source/drain contacts CA may be apart from the main gate portion 160M of the gate line 160 in the first horizontal direction (the X direction) with the insulating spacer 118 therebetween. The plurality of insulating spacers 118 may be arranged one-by-one between each of the plurality of gate lines 160 and each of the plurality of source/drain contacts CA.

As shown in FIGS. 3A, 3C, and 3E, each of the plurality of source/drain contacts CA may have a second upper surface CAT1 extending flat in the horizontal direction, for example, the first horizontal direction (the X direction) and the second horizontal direction (the Y direction), at the first vertical level LV1. Portions, which are around the second upper surface CAT1, of the upper surface of each of the plurality of source/drain contacts CA may include a contact recess surface CAR extending at a vertical level that is lower than that of the second upper surface CAT1.

As shown in FIGS. 3A, 3B, and 3D, a first metal-containing conductive liner 174A and a gate contact CB may be sequentially stacked in the stated order on the first upper surface 160T1 of each of the plurality of gate lines 160. A plurality of gate contacts CB respectively arranged over the plurality of gate lines 160 may each have a lower surface at a second vertical level LV2 that is higher than the first vertical level LV1. Each of the plurality of gate contacts CB may be apart from the gate line 160 corresponding thereto in the vertical direction (the Z direction) with the first metal-containing conductive liner 174A therebetween and may be configured to be connected to the corresponding gate line 160 via the first metal-containing conductive liner 174A.

The first metal-containing conductive liner 174A may be arranged between the first vertical level LV1 and the second vertical level LV2 and may be in contact with the first upper surface 160T1 of the gate line 160. The first metal-containing conductive liner 174A may be arranged between the first upper surface 160T1 of the gate line 160 and a lower surface (which may be referred to as a first lower surface, herein), which faces the gate line 160 of the gate contact CB. In the first horizontal direction (the X direction), a width 174AW of the first metal-containing conductive liner 174A and a width CBW of the gate contact CB may each be greater than a width 160W of the first upper surface 160T1 of the gate line 160. The first metal-containing conductive liner 174A may include portions covering the upper surface of the insulating spacer 118 (which may be referred to as a first insulating spacer, herein) that is selected from the plurality of insulating spacers 118 and adjacent to the first upper surface 160T1 of the gate line 160.

As shown in FIGS. 3A, 3C, and 3E, a second metal-containing conductive liner 174B and a source/drain via contact VA may be sequentially stacked in the stated order on the second upper surface CAT1 of each of the plurality of source/drain contacts CA. A plurality of source/drain via contacts VA respectively arranged over the plurality of source/drain contacts CA may each have a lower surface at the second vertical level LV2 that is higher than the first vertical level LV1. Each of the plurality of source/drain via contacts VA may be apart from the source/drain contact CA corresponding thereto in the vertical direction (the Z direction) with the second metal-containing conductive liner 174B therebetween and may be configured to be connected to the corresponding source/drain contact CA via the second metal-containing conductive liner 174B.

The second metal-containing conductive liner 174B may be arranged between the first vertical level LV1 and the second vertical level LV2 and may be in contact with the second upper surface CAT1 of the source/drain contact CA. The second metal-containing conductive liner 174B may be arranged between the second upper surface CAT1 of the source/drain contact CA and a lower surface (which may be referred to as a second lower surface, herein), which faces the source/drain contact CA, of the source/drain via contact VA. In the first horizontal direction (the X direction), a width 174BW of the second metal-containing conductive liner 174B and a width VAW of the source/drain via contact VA may each be greater than a width CAW of the second upper surface CAT1 of the source/drain contact CA. The second metal-containing conductive liner 174B may include portions covering the upper surface of the insulating spacer 118 (which may be referred to as a second insulating spacer, herein) that is selected from the plurality of insulating spacers 118 and adjacent to the second upper surface CAT1 of the source/drain contact CA.

As shown in FIG. 3A, the first metal-containing conductive liner 174A and the second metal-containing conductive liner 174B may be arranged at the same vertical level between the first vertical level LV1 and the second vertical level LV2. The first metal-containing conductive liner 174A and the second metal-containing conductive liner 174B may include the same metal element. In some implementations, the first metal-containing conductive liner 174A and the second metal-containing conductive liner 174B may each have a single-film structure including a conductive metal nitride film or a multi-film structure including a combination of a conductive metal nitride film and a metal film. In some implementations, the first metal-containing conductive liner 174A and the second metal-containing conductive liner 174B may include the same material that includes Ti, TiN, Ta, TaN, Mo, W, Ru, Nb, Ni, Co, Pt, Yb, Tb, Dy, Er, Pd, or any combination thereof. For example, each of the first metal-containing conductive liner 174A and the second metal-containing conductive liner 174B may include, but is not limited to, TiN.

In some implementations, the plurality of source/drain contacts CA, the plurality of gate contacts CB, and the plurality of source/drain via contacts VA may each include a metal plug and a conductive barrier film surrounding the metal plug. The metal plug may include, but is not limited to, molybdenum (Mo), tungsten (W), cobalt (Co), ruthenium (Ru), manganese (Mn), titanium (Ti), tantalum (Ta), aluminum (Al), copper (Cu), any combination thereof, or an alloy thereof. The conductive barrier film may include a metal or a conductive metal nitride. For example, the conductive barrier film may include, but is not limited to, Ti, Ta, W, TiN, TaN, WN, WCN, TiSiN, TaSiN, WSiN, or any combination thereof. In some implementations, in each of the plurality of source/drain contacts CA, the plurality of gate contacts CB, and the plurality of source/drain via contacts VA, the conductive barrier film may be omitted.

A capping insulating pattern 180 may fill a space between the plurality of gate contacts CB and the plurality of source/drain via contacts VA. A sidewall of each of a plurality of first metal-containing conductive liners 174A, a sidewall of each of a plurality of second metal-containing conductive liners 174B, a sidewall of each of the plurality of gate contacts CB, a sidewall of each of the plurality of source/drain via contacts VA, the gate recess surface 160R of each of the plurality of gate lines 160, and the contact recess surface CAR of each of the plurality of source/drain contacts CA may each be in contact with the capping insulating pattern 180. The capping insulating pattern 180 may include a silicon nitride film.

As shown in FIGS. 3A to 3E, a back-end-of-line (BEOL) structure 190 may be arranged on the plurality of gate contacts CB and the plurality of source/drain via contacts VA. The BEOL structure 190 may include a plurality of wiring layers. A wiring layer closest to the substrate 102, among the plurality of wiring layers of the BEOL structure 190, may include a first wiring layer M1A, which is integrally connected to the gate contact CB, and a second wiring layer M1B, which is integrally connected to the source/drain via contact VA. The first wiring layer M1A and the second wiring layer M1B may protrude from the upper surface of the capping insulating pattern 180 in the vertical direction (the Z direction).

The first wiring layer M1A is apart from the first metal-containing conductive liner 174A in the vertical direction (the Z direction) with the gate contact CB therebetween. Although FIGS. 3A, 3B, and 3D each illustrate a dashed line between the first wiring layer M1A and the gate contact CB, this is only for distinguishing the first wiring layer M1A and the gate contact CB from each other for convenience, and the first wiring layer M1A and the gate contact CB may be present as one component in which the first wiring layer M1A and the gate contact CB are integrally connected to each other with no interface therebetween.

The second wiring layer M1B is apart from the second metal-containing conductive liner 174B in the vertical direction (the Z direction) with the source/drain via contact VA therebetween. Although FIGS. 3A, 3C, and 3E each illustrate a dashed line between the second wiring layer M1B and the source/drain via contact VA, this is only for distinguishing the second wiring layer M1B and the source/drain via contact VA from each other for convenience, and the second wiring layer M1B and the source/drain via contact VA may be present as one component in which the second wiring layer M1B and the source/drain via contact VA are integrally connected to each other with no interface therebetween.

The integrated circuit device 100 described with reference to FIGS. 2 and 3A to 3E includes the gate line 160 and the source/drain via contact VA, which are arranged at the same vertical level. The first upper surface 160T1 of the gate line 160 and the upper surface of the insulating spacer 118 arranged therearound are covered by the first metal-containing conductive liner 174A and the gate contact CB. In addition, the second upper surface CAT1 of the source/drain contact CA and the insulating spacer 118 arranged therearound are covered by the second metal-containing conductive liner 174B and the source/drain via contact VA. The gate contact CB, which is an upper conductive pattern, is arranged on the first metal-containing conductive liner 174A, which covers the first upper surface 160T1 of the gate line 160 that is a lower conductive pattern and is configured to be connected to the gate contact CB via the first metal-containing conductive liner 174A. In addition, the source/drain via contact VA, which is another upper conductive pattern, is arranged on the second metal-containing conductive liner 174B, which covers the second upper surface CAT1 of the source/drain contact CA that is another lower conductive pattern and is configured to be connected to the source/drain contact CA via the second metal-containing conductive liner 174B. To fabricate the integrated circuit device 100 having such a structure, when a plurality of openings H1 and H2 (see FIG. 24) for forming the gate contact CB and the source/drain via contact VA are formed, a metal-containing conductive liner 174 (see FIG. 24), which is formed in advance for forming the first metal-containing conductive liner 174A and the second metal-containing conductive liner 174B, may be used as an etch stop film, whereby sufficient etch selectivity may be secured, and as a result, each of the gate contact CB and the source/drain via contact VA may secure a sufficient insulating distance from the gate line 160 and/or the source/drain contact CA adjacent thereto.

In addition, the first metal-containing conductive liner 174A may provide an electrical connection path between the gate line 160 that is a lower conductive pattern and the gate contact CB that is an upper conductive pattern, and the second metal-containing conductive liner 174B may provide an electrical connection path between the source/drain contact CA that is another lower conductive pattern and the source/drain via contact VA that is another upper conductive pattern. Therefore, after the plurality of openings H1 and H2 (see FIG. 24) are formed by using the first metal-containing conductive liner 174A and the second metal-containing conductive liner 174B as an etch stop film, without the need to remove the first metal-containing conductive liner 174A and the second metal-containing conductive liner 174B, the gate contact CB may be formed on the first metal-containing conductive liner 174A, and the source/drain via contact VA may be formed on the second metal-containing conductive liner 174B. Therefore, sufficient contact areas may be secured between the lower conductive patterns and the upper conductive patterns, which are connected to each other respectively via the first metal-containing conductive liner 174A and the second metal-containing conductive liner 174B, and thus, the resistance in conductive structures having connections respectively via the first metal-containing conductive liner 174A and the second metal-containing conductive liner 174B may be reduced, thereby improving the reliability of the integrated circuit device 100.

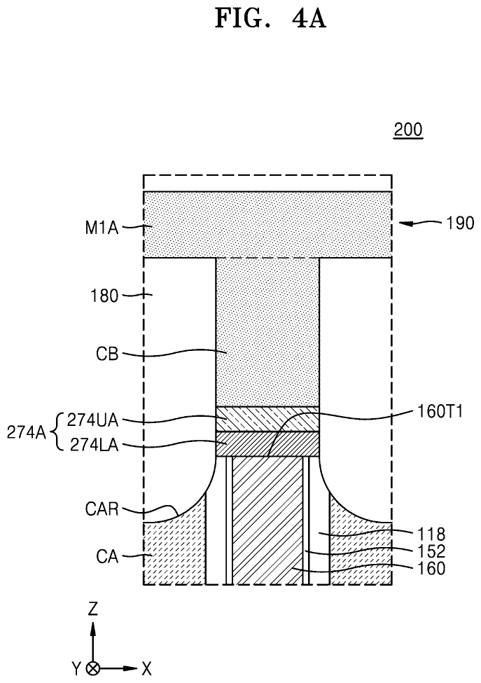

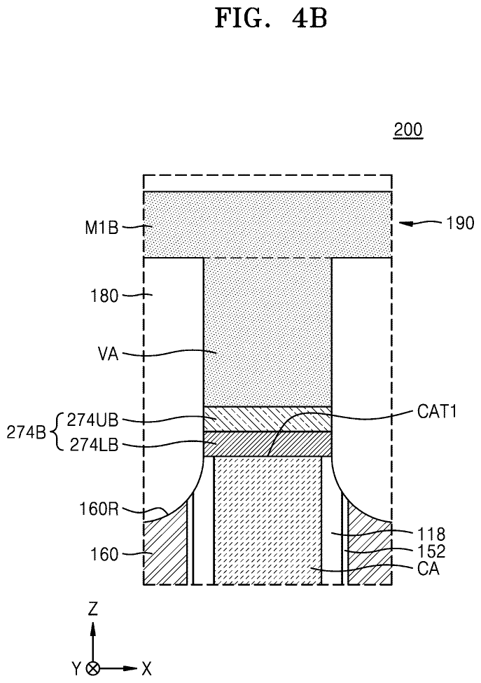

FIGS. 4A and 4B are cross-sectional views illustrating an integrated circuit device 200 according to some implementations, and in particular, FIG. 4A is an enlarged cross-sectional view of a region of the integrated circuit device 200, which corresponds to the region EX1 of FIG. 3A, and FIG. 4B is an enlarged cross-sectional view of a region of the integrated circuit device 200, which corresponds to the region EX2 of FIG. 3A. In FIGS. 4A and 4B, the same reference numerals as in FIGS. 2 and 3A to 3E respectively denote the same members, and here, repeated descriptions thereof are omitted. Components of the integrated circuit device 200 described with reference to FIGS. 4A and 4B may constitute a portion of the plurality of cells LC shown in FIG. 1.

Referring to FIGS. 4A and 4B, the integrated circuit device 200 has substantially the same configuration as the integrated circuit device 100 described with reference to FIGS. 2 and 3A to 3E. However, the integrated circuit device 200 shown in FIGS. 4A and 4B includes a first metal-containing conductive liner 274A covering the first upper surface 160T1 of the gate line 160 and a second metal-containing conductive liner 274B covering the second upper surface CAT1 of the source/drain contact CA. The first metal-containing conductive liner 274A and the second metal-containing conductive liner 274B respectively have substantially the same configurations as the first metal-containing conductive liner 174A and the second metal-containing conductive liner 174B described with reference to FIGS. 3A to 3E. In the first horizontal direction (the X direction), the first metal-containing conductive liner 274A may have a width that is greater than the width of the first upper surface 160T1 of the gate line 160 corresponding thereto, and the second metal-containing conductive liner 274B may have a width that is greater than the width of the second upper surface CAT1 of the source/drain contact CA corresponding thereto.

The first metal-containing conductive liner 274A has a multilayer structure including a first lower conductive liner 274LA and a first upper conductive liner 274UA. The second metal-containing conductive liner 274B has a multilayer structure including a second lower conductive liner 274LB and a second upper conductive liner 274UB. In some implementations, the first lower conductive liner 274LA and the first upper conductive liner 274UA of the first metal-containing conductive liner 274A and the second lower conductive liner 274LB and the second upper conductive liner 274UB of the second metal-containing conductive liner 274B may each include a material that includes Ti, TiN, Ta, TaN, Mo, W, Ru, Nb, Ni, Co, Pt, Yb, Tb, Dy, Er, Pd, or any combination thereof. The first lower conductive liner 274LA and the second lower conductive liner 274LB may include the same metal-containing film. The first upper conductive liner 274UA and the second upper conductive liner 274UB may include the same metal-containing film. For example, each of the first lower conductive liner 274LA and the second lower conductive liner 274LB may include Mo and each of the first upper conductive liner 274UA and the second upper conductive liner 274UB may include TiN, but the present disclosure is not limited thereto.

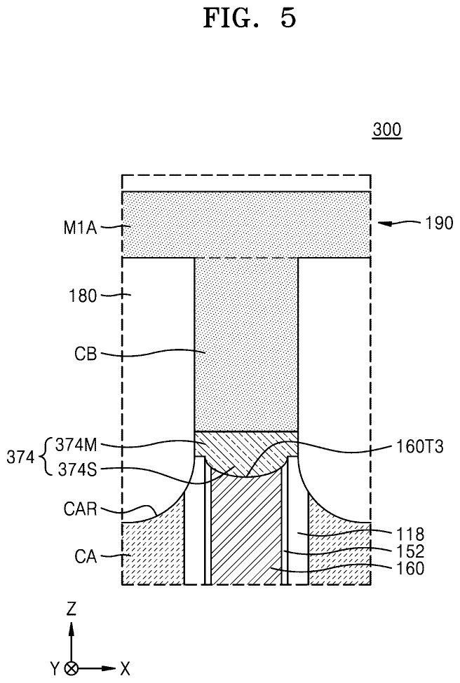

FIG. 5 is a cross-sectional view illustrating an integrated circuit device 300 according to some implementations. FIG. 5 illustrates an enlarged cross-sectional configuration of a region of the integrated circuit device 300, which corresponds to the region EX1 of FIG. 3A. In FIG. 5, the same reference numerals as in FIGS. 2 and 3A to 3E respectively denote the same members, and here, repeated descriptions thereof are omitted. Components of the integrated circuit device 300 described with reference to FIG. 5 may constitute a portion of the plurality of cells LC shown in FIG. 1.

Referring to FIG. 5, the integrated circuit device 300 has substantially the same configuration as the integrated circuit device 100 described with reference to FIGS. 2 and 3A to 3E. However, the integrated circuit device 300 shown in FIG. 5 includes a metal-containing conductive liner 374 covering a first upper surface 160T3 of the gate line 160. The metal-containing conductive liner 374 may be in contact with the first upper surface 160T3 of the gate line 160. In the first horizontal direction (the X direction), the metal-containing conductive liner 374 may have a width that is greater than the width of the first upper surface 160T3 of the gate line 160.

The first upper surface 160T3 of the gate line 160 may have a cross-sectional shape that is concave toward the metal-containing conductive liner 374. The metal-containing conductive liner 374 may include a liner body portion 374M, which further protrudes toward the outside of the gate line 160 in the first horizontal direction (the X direction) than the first upper surface 160T3 of the gate line 160, and a sagging portion 374S integrally connected to the liner body portion 374M. The sagging portion 374S of the metal-containing conductive liner 374 may protrude from the liner body portion 374M toward the gate line 160 to have a convex shape toward the first upper surface 160T3 of the gate line 160. The metal-containing conductive liner 374 may cover the first upper surface 160T3 of the gate line 160, which corresponds thereto, and the upper surface of the insulating spacer 118 adjacent to the first upper surface 160T3 of the gate line 160. A more detailed configuration of the metal-containing conductive liner 374 is substantially the same as that of the first metal-containing conductive liner 174A described with reference to FIGS. 3A, 3B, and 3D.

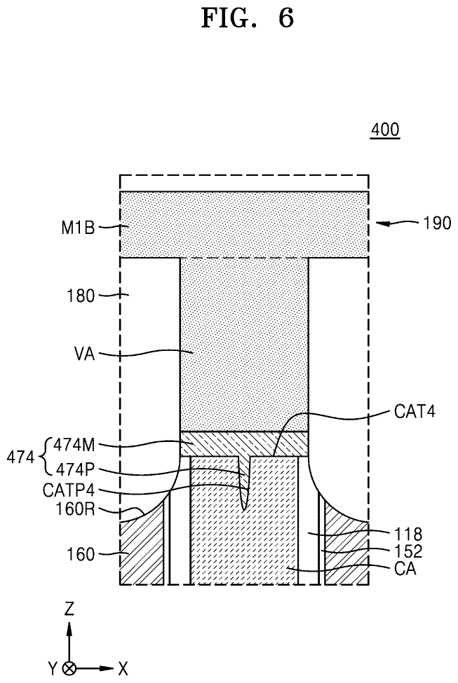

FIG. 6 is a cross-sectional view illustrating an integrated circuit device 400 according to some implementations. FIG. 6 illustrates an enlarged cross-sectional configuration of a region of the integrated circuit device 400, which corresponds to the region EX2 of FIG. 3A. In FIG. 6, the same reference numerals as in FIGS. 2 and 3A to 3E respectively denote the same members, and here, repeated descriptions thereof are omitted. Components of the integrated circuit device 400 described with reference to FIG. 6 may constitute a portion of the plurality of cells LC shown in FIG. 1.

Referring to FIG. 6, the integrated circuit device 400 has substantially the same configuration as the integrated circuit device 100 described with reference to FIGS. 2 and 3A to 3E. However, the integrated circuit device 400 shown in FIG. 6 includes a metal-containing conductive liner 474 covering a second upper surface CAT4 of the source/drain contact CA. The metal-containing conductive liner 474 may be in contact with the second upper surface CAT4 of the source/drain contact CA. In the first horizontal direction (the X direction), the metal-containing conductive liner 474 may have a width that is greater than the width of the second upper surface CAT4 of the source/drain contact CA.

The second upper surface CAT4 of the source/drain contact CA may have a dent portion CATP4 that is locally concave toward the metal-containing conductive liner 474. The metal-containing conductive liner 474 may include a liner body portion 474M, which further protrudes toward the outside of the source/drain contact CA in the first horizontal direction (the X direction) than the second upper surface CAT4 of the source/drain contact CA, and a protruding portion 474P integrally connected to the liner body portion 474M. The protruding portion 474P of the metal-containing conductive liner 474 may protrude from the liner body portion 474M toward the source/drain contact CA to fill the dent portion CATP4 of the source/drain contact CA. The metal-containing conductive liner 474 may cover the second upper surface CAT4 of the source/drain contact CA, which corresponds thereto, and the upper surface of the insulating spacer 118 adjacent to the second upper surface CAT4 of the source/drain contact CA. A more detailed configuration of the metal-containing conductive liner 474 is substantially the same as that of the second metal-containing conductive liner 174B described with reference to FIGS. 3A, 3C, and 3E.

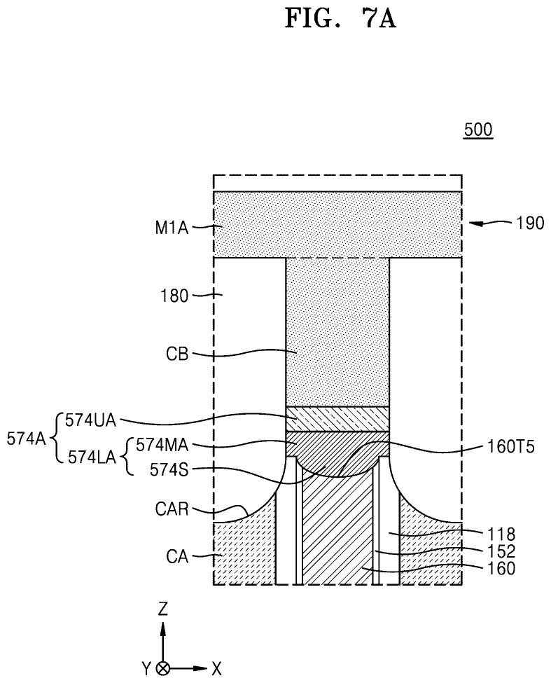

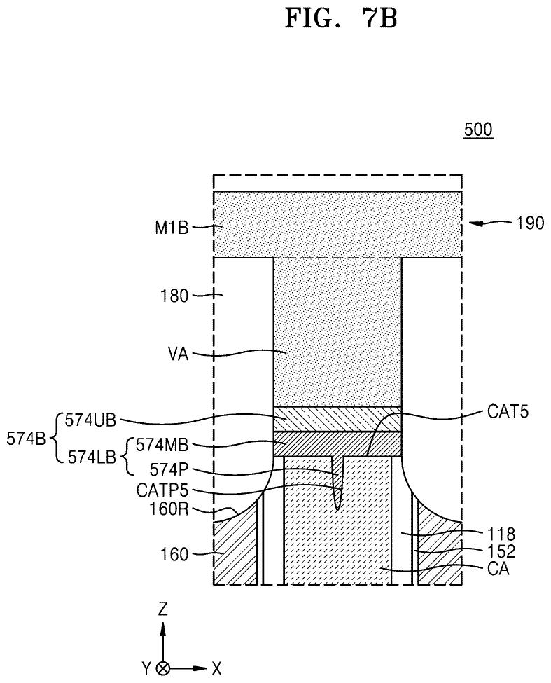

FIGS. 7A and 7B are cross-sectional views illustrating an integrated circuit device 500 according to some implementations, and in particular, FIG. 7A is an enlarged cross-sectional view of a region of the integrated circuit device 500, which corresponds to the region EX1 of FIG. 3A, and FIG. 7B is an enlarged cross-sectional view of a region of the integrated circuit device 500, which corresponds to the region EX2 of FIG. 3A. In FIGS. 7A and 7B, the same reference numerals as in FIGS. 2 and 3A to 3E respectively denote the same members, and here, repeated descriptions thereof are omitted. Components of the integrated circuit device 500 described with reference to FIGS. 7A and 7B may constitute a portion of the plurality of cells LC shown in FIG. 1.

Referring to FIGS. 7A and 7B, the integrated circuit device 500 has substantially the same configuration as the integrated circuit device 100 described with reference to FIGS. 2 and 3A to 3E. However, the integrated circuit device 500 shown in FIGS. 7A and 7B includes a first metal-containing conductive liner 574A covering a first upper surface 160T5 of the gate line 160 and a second metal-containing conductive liner 574B covering a second upper surface CAT5 of the source/drain contact CA. The first metal-containing conductive liner 574A and the second metal-containing conductive liner 574B respectively have substantially the same configurations as the first metal-containing conductive liner 174A and the second metal-containing conductive liner 174B described with reference to FIGS. 3A to 3E. In the first horizontal direction (the X direction), the first metal-containing conductive liner 574A may have a width that is greater than the width of the first upper surface 160T5 of the gate line 160 corresponding thereto, and the second metal-containing conductive liner 574B may have a width that is greater than the width of the second upper surface CAT5 of the source/drain contact CA corresponding thereto. However, each of the first metal-containing conductive liner 574A and the second metal-containing conductive liner 574B has a multilayer structure.

The first metal-containing conductive liner 574A has a multilayer structure including a first lower conductive liner 574LA and a first upper conductive liner 574UA. The first upper surface 160T5 of the gate line 160 may have a cross-sectional shape that is concave toward the first metal-containing conductive liner 574A. The first lower conductive liner 574LA of the first metal-containing conductive liner 574A may include a liner body portion 574MA, which further protrudes toward the outside of the gate line 160 in the first horizontal direction (the X direction) than the first upper surface 160T5 of the gate line 160 (in other words, the liner body portion 574MA may protrude beyond the first upper surface 160T5 of the gate line 160 in Z direction) and a sagging portion 574S integrally connected to the liner body portion 574MA. The sagging portion 574S of the first lower conductive liner 574LA of the first metal-containing conductive liner 574A may protrude from the liner body portion 574MA toward the gate line 160 to have a convex shape toward the first upper surface 160T5 of the gate line 160. The first lower conductive liner 574LA of the first metal-containing conductive liner 574A may be in contact with the first upper surface 160T5 of the gate line 160. In the first metal-containing conductive liner 574A, the upper surface of the first lower conductive liner 574LA and the lower surface of the first upper conductive liner 574UA may be in contact with each other. The first metal-containing conductive liner 574A may cover the first upper surface 160T5 of the gate line 160, which corresponds thereto, and the upper surface of the insulating spacer 118 adjacent to the first upper surface 160T5 of the gate line 160. A more detailed configuration of the first metal-containing conductive liner 574A is substantially the same as that of the first metal-containing conductive liner 174A described with reference to FIGS. 3A, 3B, and 3D.

The second metal-containing conductive liner 574B has a multilayer structure including a second lower conductive liner 574LB and a second upper conductive liner 574UB. In the first horizontal direction (the X direction), the second metal-containing conductive liner 574B may have a width that is greater than the width of the second upper surface CAT5 of the source/drain contact CA.

The second upper surface CAT5 of the source/drain contact CA may have a dent portion CATP5 that is locally concave toward the second metal-containing conductive liner 574B. The second lower conductive liner 574LB of the second metal-containing conductive liner 574B may include a liner body portion 574MB, which further protrudes toward the outside of the source/drain contact CA in the first horizontal direction (the X direction) than the second upper surface CAT5 of the source/drain contact CA, and a protruding portion 574P integrally connected to the liner body portion 574MB. The protruding portion 574P of the second lower conductive liner 574LB of the second metal-containing conductive liner 574B may protrude from the liner body portion 574MB toward the source/drain contact CA to fill the dent portion CATP5 of the source/drain contact CA.

The second lower conductive liner 574LB of the second metal-containing conductive liner 574B may be in contact with the second upper surface CAT5 of the source/drain contact CA. In the second metal-containing conductive liner 574B, the upper surface of the second lower conductive liner 574LB and the lower surface of the second upper conductive liner 574UB may be in contact with each other. The second metal-containing conductive liner 574B may cover the second upper surface CAT5 of the source/drain contact CA, which corresponds thereto, and the upper surface of the insulating spacer 118 adjacent to the second upper surface CAT5 of the source/drain contact CA. A more detailed configuration of the second metal-containing conductive liner 574B is substantially the same as that of the second metal-containing conductive liner 174B described with reference to FIGS. 3A, 3C, and 3E.

In some implementations, the first lower conductive liner 574LA and the first upper conductive liner 574UA of the first metal-containing conductive liner 574A and the second lower conductive liner 574LB and the second upper conductive liner 574UB of the second metal-containing conductive liner 574B may each include a material selected from Ti, TiN, Ta, TaN, Mo, W, Ru, Nb, Ni, Co, Pt, Yb, Tb, Dy, Er, Pd, and any combination thereof. The first lower conductive liner 574LA and the second lower conductive liner 574LB may include the same metal-containing film. The first upper conductive liner 574UA and the second upper conductive liner 574UB may include the same metal-containing film. For example, each of the first lower conductive liner 574LA and the second lower conductive liner 574LB may include Mo and each of the first upper conductive liner 574UA and the second upper conductive liner 574UB may include TiN, but the present disclosure is not limited thereto.

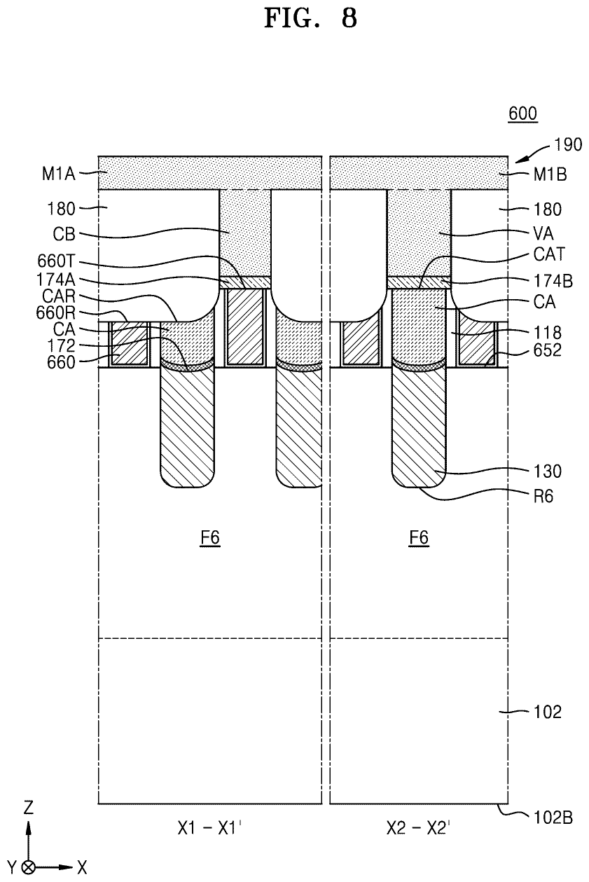

FIG. 8 is a cross-sectional view illustrating an integrated circuit device 600 according to some implementations. FIG. 8 illustrates components of regions of the integrated circuit device 600, the regions respectively corresponding to cross-sections taken along the line X1-X1′ of FIG. 2 and the line X2-X2′ of FIG. 2. In FIG. 8, the same reference numerals as in FIGS. 2 and 3A to 3E respectively denote the same members, and here, repeated descriptions thereof are omitted.

Referring to FIG. 8, the integrated circuit device 600 may include a fin field-effect transistor (FinFET) device. The components of the integrated circuit device 600 described with reference to FIG. 8 may constitute a portion of the plurality of cells LC shown in FIG. 1.

The integrated circuit device 600 may include a fin-type active region F6 protruding from the substrate 102. The fin-type active region F6 may have substantially the same configuration as the fin-type active region F1 described with reference to FIGS. 2 and 3A to 3C. The device isolation film 112 may cover a lower sidewall of the fin-type active region F6.

A plurality of gate dielectric films 652 and a plurality of gate lines 660 may extend lengthwise in the second horizontal direction (the Y direction) on or over the fin-type active region F6. The plurality of gate dielectric films 652 and the plurality of gate lines 660 may cover an upper surface of each of a plurality of fin-type active regions F6 and both sidewalls, in the second horizontal direction (the Y direction), of each of the plurality of fin-type active regions F6. Each of the plurality of gate dielectric films 652 and each of the plurality of gate lines 660 may respectively have substantially the same configurations as the gate dielectric film 152 and the gate line 160, which are described with reference to FIGS. 2 and 3A to 3E. The plurality of insulating spacers 118 may respectively cover both sidewalls of each of the plurality of gate lines 660. A plurality of MOS transistors may be formed along each of the plurality of gate lines 660. Each of the plurality of MOS transistors may include a 3-dimensional-structure MOS transistor in which a channel is formed at the upper surface and both sidewalls of each of the plurality of fin-type active regions F6. Each of the plurality of MOS transistors may include an NMOS transistor, a PMOS transistor, or a combination thereof.

A plurality of recess regions R6 may be formed in the fin-type active region F6. A plurality of source/drain regions 130 may be respectively arranged in the plurality of recess regions R6. The gate line 660 and the source/drain region 130 may be apart from each other with the gate dielectric film 652 and the insulating spacer 118 therebetween.

A plurality of metal silicide films 172 may be respectively arranged on the plurality of source/drain regions 130, and a plurality of source/drain contacts CA may be respectively arranged on the plurality of metal silicide films 172. Each of the plurality of source/drain contacts CA may be apart from, in the first horizontal direction (the X direction), the gate line 660 adjacent thereto with the insulating spacer 118 therebetween. The plurality of insulating spacers 118 may be arranged one-by-one between each of the plurality of gate lines 660 and each of the plurality of source/drain contacts CA.

The first metal-containing conductive liner 174A and the gate contact CB may be sequentially stacked in the stated order on a first upper surface 660T of each of the plurality of gate lines 660. Portions, which are around the first upper surface 660T, of the upper surface of each of the plurality of gate lines 660 may include a gate recess surface 660R extending at a vertical level lower than that of the first upper surface 660T. The second metal-containing conductive liner 174B and the source/drain via contact VA may be sequentially stacked in the stated order on a second upper surface CAT of each of the plurality of source/drain contacts CA. Portions, which are around the second upper surface CAT, of the upper surface of each of the plurality of source/drain contacts CA may include a contact recess surface CAR extending at a vertical level lower than that of the second upper surface CAT.

A wiring layer closest to the substrate 102, among the plurality of wiring layers of the BEOL structure 190, may include a first wiring layer M1A, which is integrally connected to the gate contact CB, and a second wiring layer M1B, which is integrally connected to the source/drain via contact VA. More detailed configurations of the first metal-containing conductive liner 174A, the second metal-containing conductive liner 174B, the gate contact CB, and the source/drain via contact VA are the same as those described with reference to FIGS. 2 and 3A to 3E.

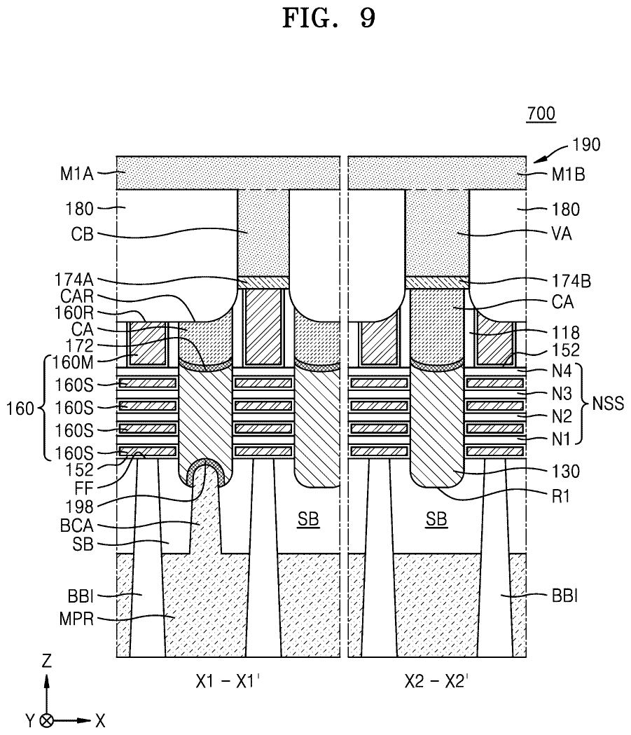

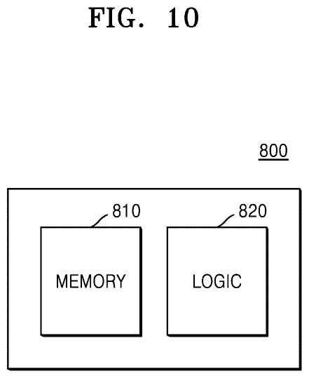

FIG. 9 is a cross-sectional view illustrating an integrated circuit device 700 according to some implementations. FIG. 9 illustrates components of regions of the integrated circuit device 700, the regions respectively corresponding to the cross-sections taken along the line X1-X1′ of FIG. 2 and the line X2-X2′ of FIG. 2. In FIG. 9, the same reference numerals as in FIGS. 2 and 3A to 3E respectively denote the same members, and here, repeated descriptions thereof are omitted.

Referring to FIG. 9, the integrated circuit device 700 has substantially the same configuration as the integrated circuit device 100 described with reference to FIGS. 2 and 3A to 3E. However, the integrated circuit device 700 includes a backside source/drain contact BCA and a backside power rail MPR connected to the backside source/drain contact BCA.

The backside source/drain contact BCA may be configured to be connected to a backside surface of a source/drain region 130 selected from the plurality of source/drain regions 130. The backside source/drain contact BCA may pass through a lower portion of a source/drain region 130 corresponding thereto in the vertical direction (the Z direction) from the back side of the source/drain region 130 corresponding thereto.

A backside metal silicide film 198 may be arranged between the source/drain region 130 connected to the backside source/drain contact BCA, among the plurality of source/drain regions 130, and the backside source/drain contact BCA. The backside source/drain contact BCA may be configured to be connected to the source/drain region 130 corresponding thereto via the backside metal silicide film 198. A constituent material of the backside metal silicide film 198 is substantially the same as the constituent material of the metal silicide film 172 described above.

Although FIG. 9 illustrates an example of a configuration in which the source/drain contact CA is connected to a frontside surface of the source/drain region 130 to which the backside source/drain contact BCA is connected, the present disclosure is not limited thereto. Unlike the example shown in FIG. 9, the source/drain contact CA may not be connected to the source/drain region 130 to which the backside source/drain contact BCA is connected. Herein, the backside surface and the frontside surface of the source/drain region 130 refer to opposite surfaces to each other in the vertical direction (the Z direction) in the source/drain region 130. The backside surface of the source/drain region 130 is a surface, which faces the backside power rail MPR, of the source/drain region 130.

The integrated circuit device 700 may include a plurality of backside bulk insulting films BBI, which are arranged in a line in the first horizontal direction (the X direction) and each extend lengthwise in the second horizontal direction (the Y direction). A plurality of backside power rails MPR may be isolated from each other in the first horizontal direction (the X direction) by the plurality of backside bulk insulting films BBI. The plurality of backside power rails MPR may be arranged one-by-one in the first horizontal direction (the X direction) between each of the plurality of backside bulk insulting films BBI. The backside source/drain contact BCA may be integrally connected to a backside power rail MPR selected from the plurality of backside power rails MPR. The plurality of nanosheet stacks NSS may be respectively arranged apart from the plurality of backside bulk insulting films BBI in the vertical direction (the Z direction). Each of the plurality of backside bulk insulting films BBI may be arranged to overlap one selected from the plurality of gate lines 160 in the vertical direction (the Z direction) to extend lengthwise in the vertical direction (the Z direction).

Each of the plurality of backside bulk insulting films BBI may be in contact with a pair of backside power rails MPR that are selected from the plurality of backside power rails MPR and adjacent to each other. Each of the plurality of backside bulk insulting films BBI may extend lengthwise in the vertical direction (the Z direction) from a space between a pair of backside power rails MPR adjacent to each other toward one selected from the plurality of gate lines 160. In some implementations, each of the plurality of backside bulk insulting films BBI may include a nitrogen-containing insulating film. For example, each of the plurality of backside bulk insulting films BBI may include, but is not limited to, silicon nitride (SiN), silicon carbonitride (SiCN), silicon oxycarbonitride (SiOCN), or any combination thereof.

The backside source/drain contact BCA may extend lengthwise in the vertical direction (the Z direction) between a pair of backside bulk insulating films BBI adjacent to each other from among the plurality of backside bulk insulting films BBI. The backside power rail MPR integrally connected to the backside source/drain contact BCA, among the plurality of backside power rails MPR, may be apart from the source/drain region 130 in the vertical direction (the Z direction) with the backside source/drain contact BCA therebetween.

In some implementations, the backside source/drain contact BCA and the backside power rail MPR may be simultaneously formed in a single process and may include the same material. In some implementations, the backside source/drain contact BCA and the backside power rail MPR may be respectively formed by separate processes, and there may be an interface between the backside source/drain contact BCA and the backside power rail MPR. In some implementations, the backside source/drain contact BCA and the backside power rail MPR may include a single metal. In some implementations, the source/drain contact CA may include a metal plug and a conductive barrier film surrounding the metal plug. The metal plug may include, but is not limited to, molybdenum (Mo), tungsten (W), cobalt (Co), ruthenium (Ru), manganese (Mn), titanium (Ti), tantalum (Ta), aluminum (Al), copper (Cu), any combination thereof, or an alloy thereof. The conductive barrier film may include a metal or a conductive metal nitride. For example, the conductive barrier film may include, but is not limited to, Ti, Ta, W, TiN, TaN, WN, WCN, TiSiN, TaSiN, WSiN, or any combination thereof.

The integrated circuit device 700 may include a plurality of semiconductor blocks SB. Some of the plurality of semiconductor blocks SB may each cover a sidewall of the backside source/drain contact BCA in the first horizontal direction (the X direction). Some others of the plurality of semiconductor blocks SB may each be in contact with the backside surface of the source/drain region 130 to which the source/drain contact CA is connected. Each of the plurality of semiconductor blocks SB may include silicon (Si).

At least some of the plurality of semiconductor blocks SB may each cover a sidewall of the backside bulk insulating film BBI in the first horizontal direction (the X direction). Each of the plurality of semiconductor blocks SB may be in contact with the gate dielectric film 152 covering the lowermost surface of the gate line 160. Herein, the lowermost surface of the gate line 160 refers to a surface, which is closest to the backside power rail MPR, of the gate line 160.

According to each of the integrated circuit devices 200, 300, 400, 500, 600, and 700 described with reference to FIGS. 4A to 9, the same effect as that of the integrated circuit device 100 described with reference to FIGS. 2 and 3A to 3E may be achieved.

FIG. 10 is a block diagram of an integrated circuit device 800 according to implementations.

Referring to FIG. 10, the integrated circuit device 800 may include a memory area 810 and a logic area 820. At least one of the memory area 810 and the logic area 820 may include at least one of the configurations of the integrated circuit devices 100, 200, 300, 400, 500, 600, and 700 described with reference to FIGS. 2 to 9.

The memory area 810 may include at least one of static random-access memory (SRAM), dynamic RAM (DRAM), magnetic RAM (MRAM), resistive RAM (RRAM), and phase-change RAM (PRAM). For example, the memory area 810 may include SRAM. The logic area 820 may include standard cells performing intended logical functions, such as a counter, a buffer, and the like. The standard cells may include various logic cells including a plurality of circuit elements, such as a transistor, a register, and the like. Each of the logic cells may constitute, for example, an AND, a NAND, an OR, a NOR, an XOR, an XNOR, an INV, an ADD, a BUF, a DLY, a FIL, an MXT/MXIT, an OAI, an AO, an AOI, a D flip-flop, a reset flip-flop, a master-slave flip-flop, a latch, or the like.

Next, a method of fabricating an integrated circuit device, according to implementations, is described in detail.

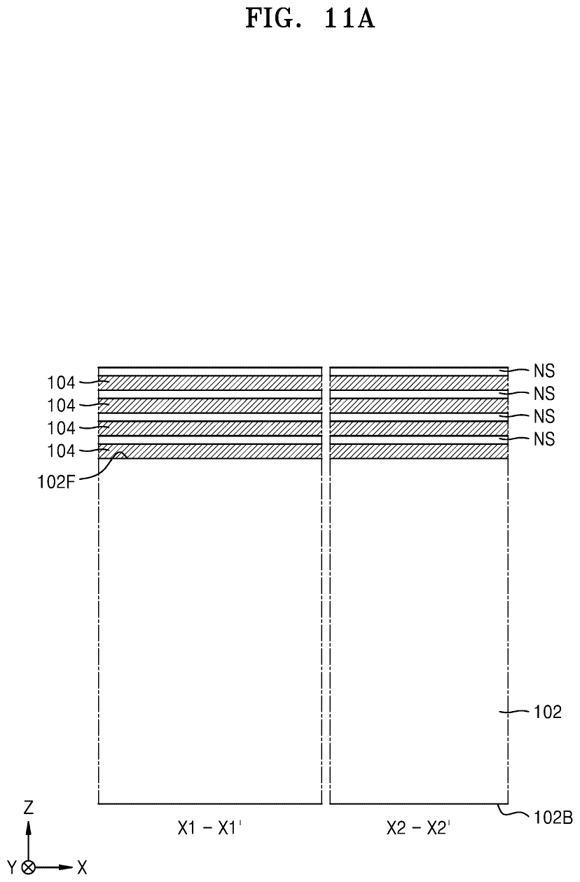

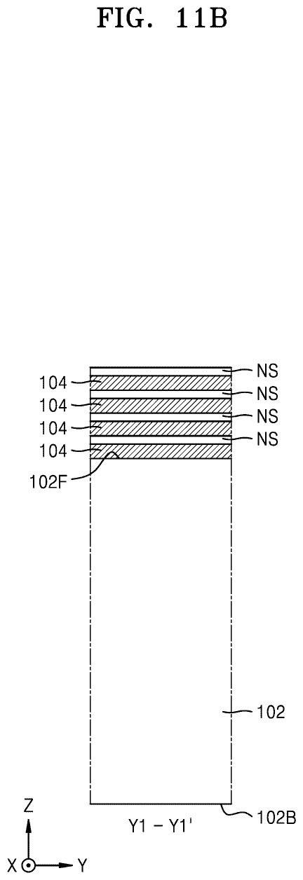

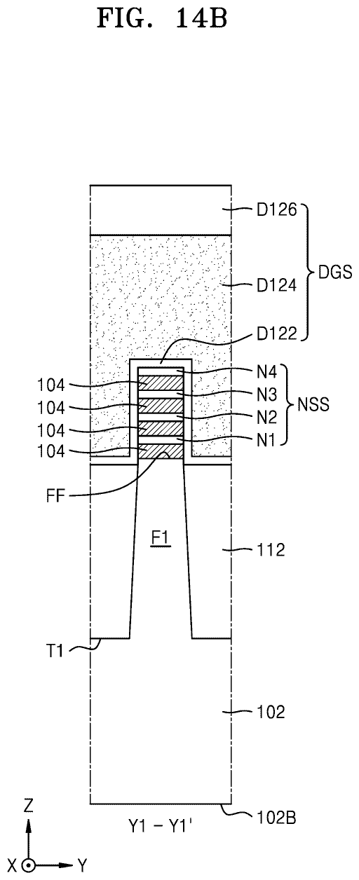

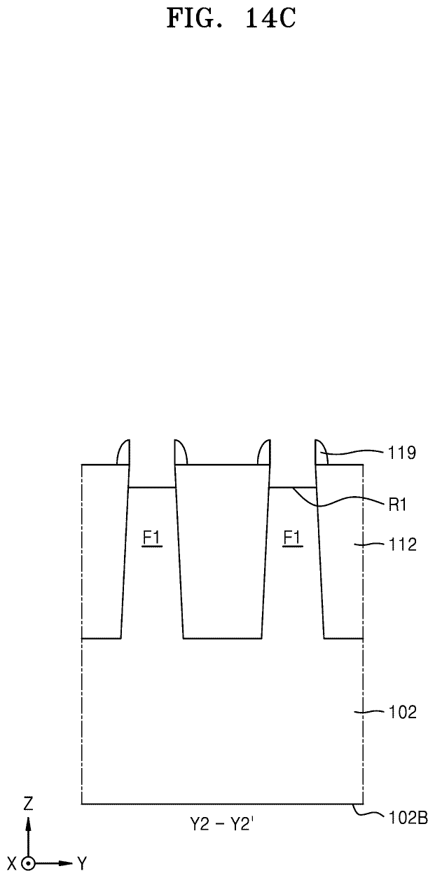

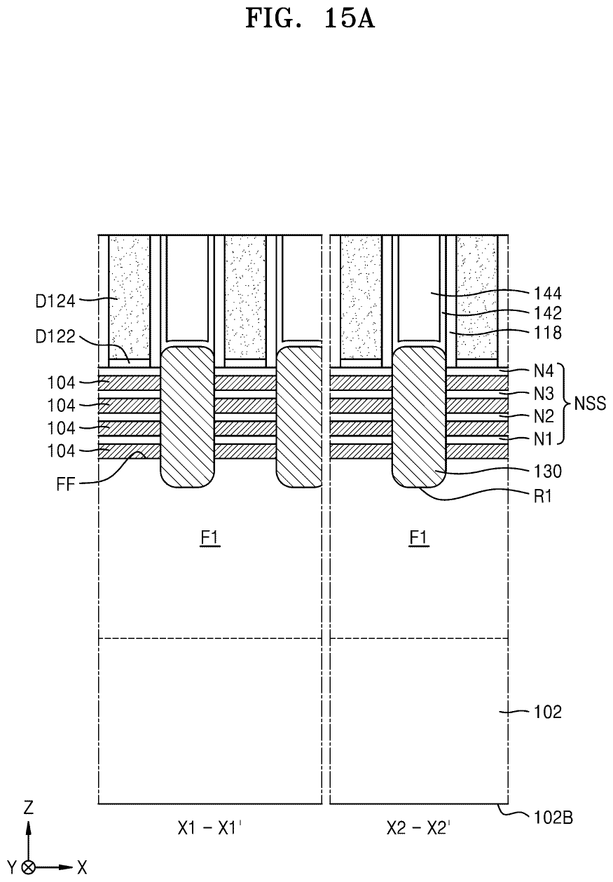

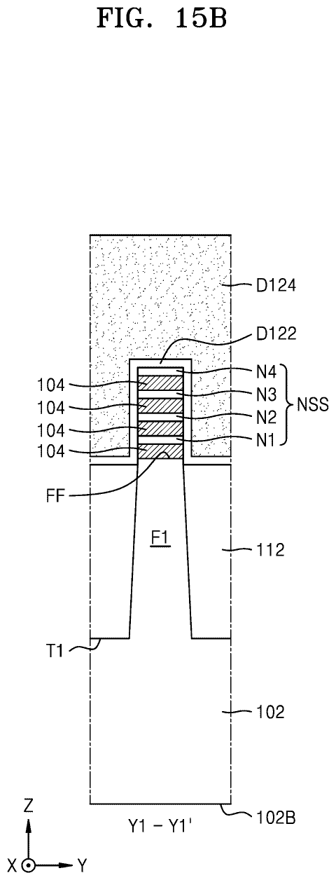

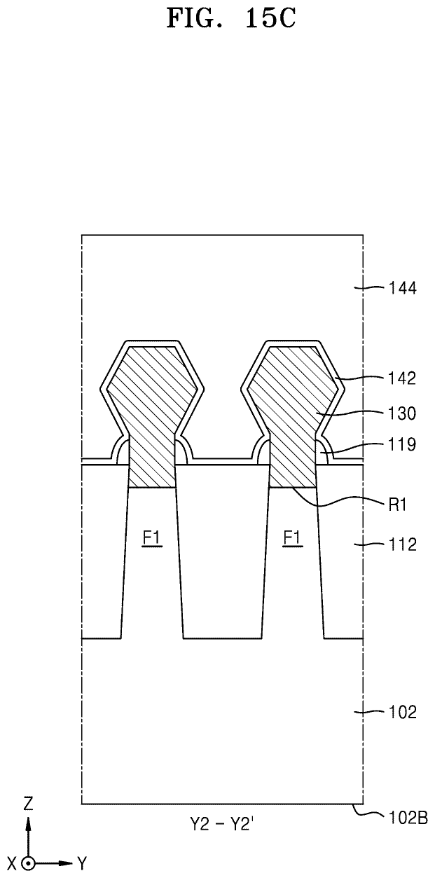

FIGS. 11A to 29 are diagrams respectively illustrating a sequence of processes of a method of fabricating an integrated circuit device, according to implementations. More specifically, FIGS. 11A, 12A, 13A, 14A, 15A, 16A, 17A, 18A, and 19 to 29 are cross-sectional views each illustrating cross-sectional structures of regions respectively corresponding to a cross-section taken along the line X1-X1′ of FIG. 2 and a cross-section taken along the line X2-X2′ of FIG. 2, according to the sequence of processes. FIGS. 11B, 12B, 13B, 14B, 15B, 16B, 17B, and 18B are cross-sectional views each illustrating a cross-sectional structure of a region corresponding to a cross-section taken along the line Y1-Y1′ of FIG. 2, according to the sequence of processes. FIGS. 14C and 15C are cross-sectional views each illustrating a cross-sectional structure of a region corresponding to a cross-section taken along the line Y2-Y2′ of FIG. 2, according to the sequence of processes. An example of a method of fabricating the integrated circuit device 100 shown in FIGS. 2 and 3A to 3E is described with reference to FIGS. 11A to 29. In FIGS. 11A to 29, the same reference numerals as in FIGS. 2 and 3A to 3E respectively denote the same members, and here, repeated descriptions thereof are omitted.

Referring to FIGS. 11A and 11B, the substrate 102 having a frontside surface 102F and a backside surface 102B may be prepared, and a stack structure, in which a plurality of sacrificial semiconductor layers 104 and a plurality of nanosheet semiconductor layers NS are alternately stacked one-by-one on the frontside surface 102F of the substrate 102, may be formed.

In the stack structure, each of the plurality of sacrificial semiconductor layers 104 and each of the plurality of nanosheet semiconductor layers NS may respectively include semiconductor materials having different etch selectivities. In some implementations, each of the plurality of nanosheet semiconductor layers NS may include a Si layer, and each of the plurality of sacrificial semiconductor layers 104 may include a SiGe layer. The SiGe layer constituting a sacrificial semiconductor layer 104 may have a constant Ge content ratio selected from a range of about 5 at % to about 50 at %, for example, about 10 at % to about 40 at %. In some implementations, each of the plurality of sacrificial semiconductor layers 104 may include a SiGe layer, and respective Ge content ratios in the plurality of sacrificial semiconductor layers 104 may be equal to each other.

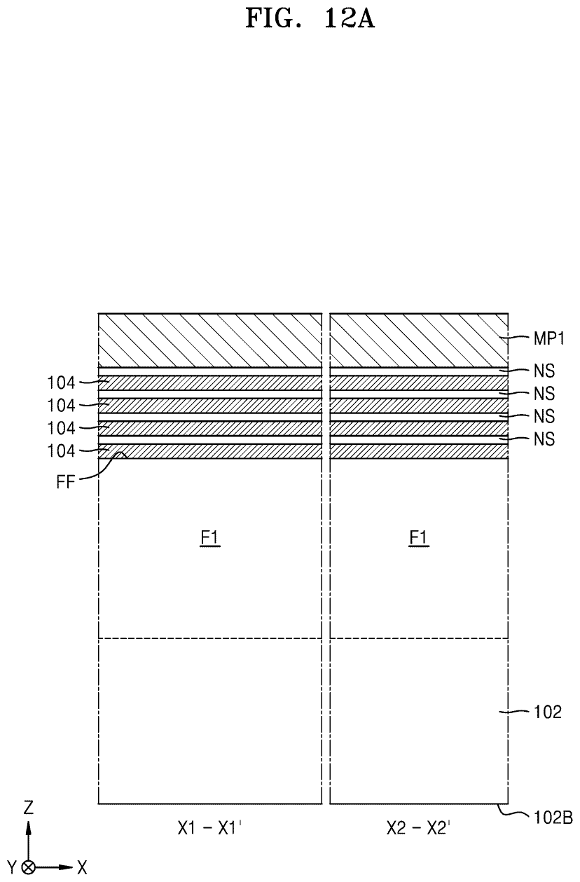

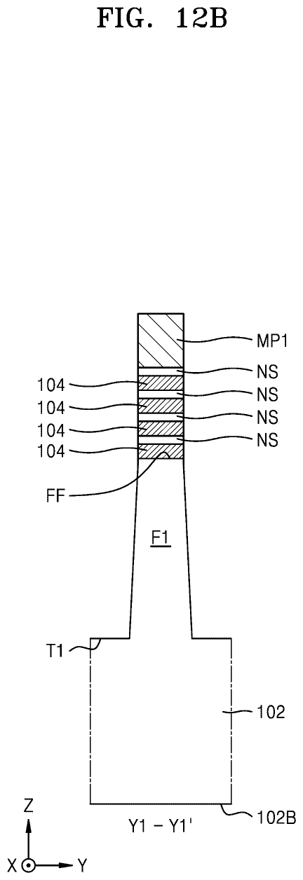

Referring to FIGS. 12A and 12B, a mask pattern MP1 having a plurality of openings, which expose the upper surface of the stack structure, may be formed on the resulting product of FIGS. 11A and 11B. The mask pattern MP1 may include a stack structure of a silicon oxide film pattern and a silicon nitride film pattern. The mask pattern MP1 may include portions extending parallel to each other in the first horizontal direction (the X direction) over the substrate 102.

The plurality of sacrificial semiconductor layers 104, the plurality of nanosheet semiconductor layers NS, and the substrate 102 may each be partially etched by using the mask pattern MP1 as an etch mask, thereby forming a plurality of fin-type active regions F1 in the substrate 102. A plurality of trenches T1 may be defined on the substrate 102 by the plurality of fin-type active regions F1. A portion of each of the plurality of sacrificial semiconductor layers 104 and the plurality of nanosheet semiconductor layers NS may remain on or over the fin top surface FF of each of the plurality of fin-type active regions F1.

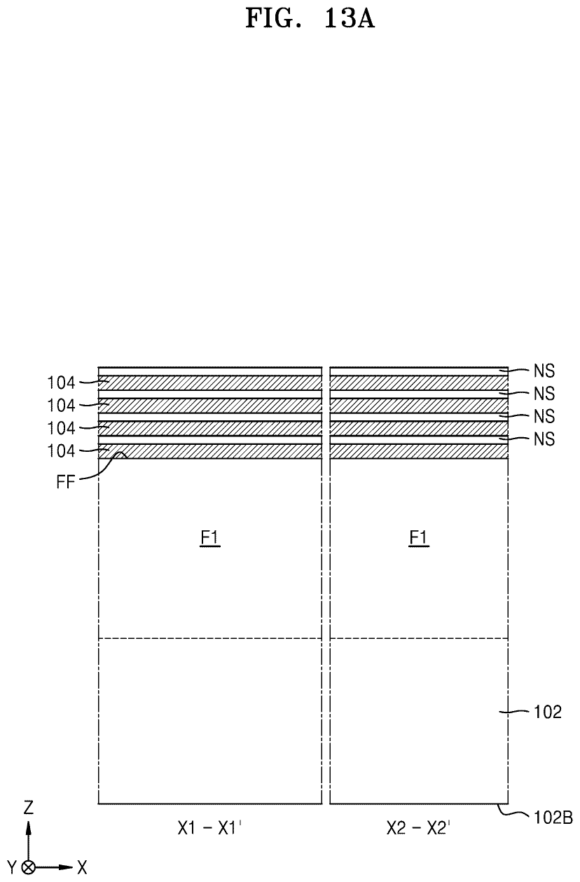

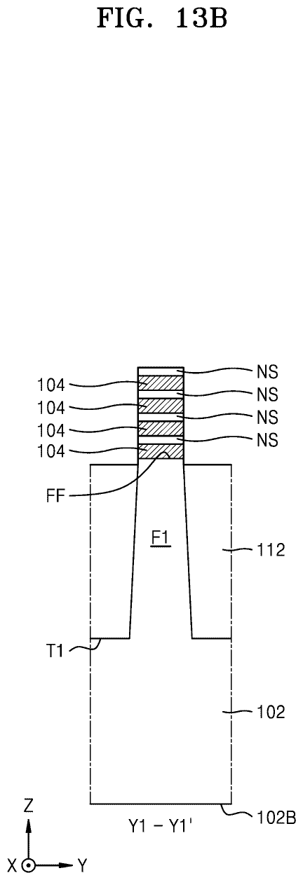

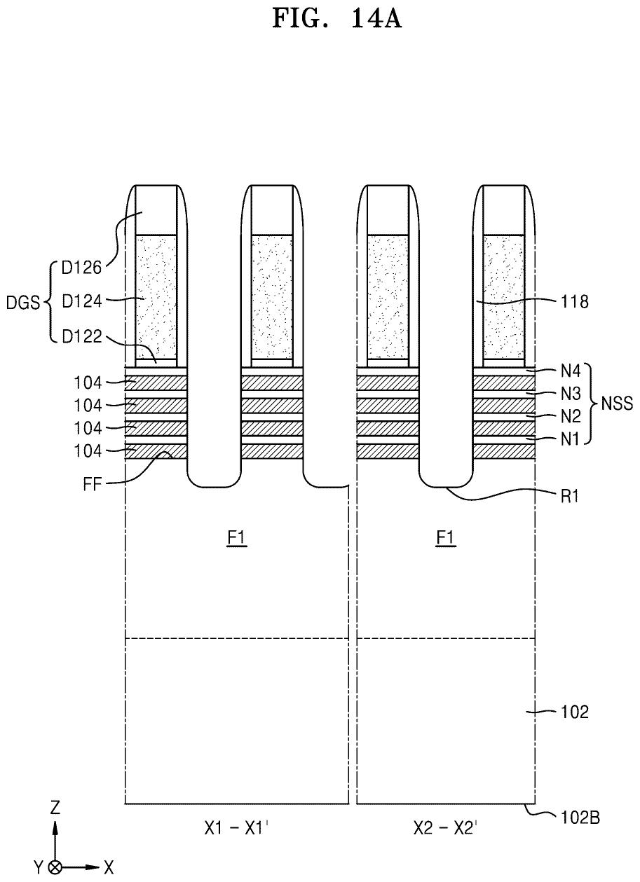

Referring to FIGS. 13A and 13B, the device isolation film 112 may be formed on the resulting product of FIGS. 12A and 12B. The device isolation film 112 may be formed to fill the plurality of trenches T1 and to cover sidewalls of each of the plurality of fin-type active regions F1.

To form the device isolation film 112, an insulating film may be formed on the resulting product of FIGS. 12A and 12B to have a thickness enough to fill the plurality of trenches T1, and the upper surface of the mask pattern MP1 may be exposed by planarizing an obtained resulting product. Next, the mask pattern MP1 that is exposed may be removed, and then, a recess process for removing a portion of the insulating film may be performed, thereby forming the device isolation film 112, which includes the remaining portion of the insulating film. After the device isolation film 112 is formed, the stack structure including the plurality of sacrificial semiconductor layers 104 and the plurality of nanosheet semiconductor layers NS, which remain on or over the substrate 102, may protrude upward from the upper surface of the device isolation film 112, and the upper surface of the uppermost nanosheet semiconductor layer NS from among the plurality of nanosheet semiconductor layers NS may be exposed.

Referring to FIGS. 14A, 14B, and 14C, a plurality of dummy gate structures DGS may be formed on the resulting product of FIGS. 13A and 13B. Each of the plurality of dummy gate structures DGS may be formed to extend lengthwise in the second horizontal direction (the Y direction). Each of the plurality of dummy gate structures DGS may include a dummy oxide film D122, a dummy gate layer D124, and a capping layer D126, which are stacked in the stated order on the stack structure including the plurality of sacrificial semiconductor layers 104 and the plurality of nanosheet semiconductor layers NS. In some implementations, the dummy gate layer D124 may include polysilicon and the capping layer D126 may include a silicon nitride film.

As shown in FIG. 14A, a plurality of insulating spacers 118 may be formed to respectively cover both sidewalls of each of the plurality of dummy gate structures DGS, and a portion of each of the plurality of sacrificial semiconductor layers 104 and the plurality of nanosheet semiconductor layers NS and a portion of the fin-type active region F1 may be etched by using the plurality of dummy gate structures DGS and the plurality of insulating spacers 118 as an etch mask, thereby dividing the plurality of nanosheet semiconductor layers NS into the plurality of nanosheet stacks NSS, which each include the first to fourth nanosheets N1, N2, N3, and N4, and forming a plurality of recesses R1 in the fin-type active region F1. The width of each of the first to fourth nanosheets N1, N2, N3, and N4 in the first horizontal direction (the X direction) may be defined by the plurality of recesses R1.

To form the plurality of recesses R1, the etching may be performed by dry etching, wet etching, or a combination thereof. During the formation of the plurality of insulating spacers 118 and the plurality of recesses R1, the plurality of side insulating spacers 119 may be formed as shown in FIG. 14C, the plurality of side insulating spacers 119 being arranged on the device isolation film 112 on both sides of each fin-type active region F1 in the second horizontal direction (the Y direction) to be respectively adjacent to the plurality of recesses R1.

Referring to FIGS. 15A, 15B, and 15C, in the resulting product of FIGS. 14A, 14B, and 14C, the plurality of source/drain regions 130 may be formed to respectively fill the plurality of recesses R1. To form the plurality of source/drain regions 130, a semiconductor material may be epitaxially grown on the respective sidewalls of the first to fourth nanosheets N1, N2, N3, and N4 and the surface of the fin-type active region F1, which are exposed in each of the plurality of recesses R1.

In some implementations, to form the plurality of source/drain regions 130, a low-pressure chemical vapor deposition (LPCVD) process, a selective epitaxial growth (SEG) process, or a cyclic deposition and etching (CDE) process may be performed by using source materials including an elemental semiconductor precursor. The elemental semiconductor precursor may include an element, such as Si or Ge.

In some implementations, the plurality of source/drain regions 130 may each include a SiGe layer doped with boron (B). In this case, to form the plurality of source/drain regions 130, the substrate 102 may be in-situ doped with boron (B) ions while supplying a Si source and a Ge source onto the substrate 102. The Si source may include, but is not limited to, silane (SiH₄), disilane (Si₂H₆), trisilane (Si₃H₈), dichlorosilane (SiH₂Cl₂), or the like. The Ge source may include, but is not limited to, germane (GeH₄), digermane (Ge₂H₆), trigermane (Ge₃H₈), tetragermane (Ge₄H₁₀), dichlorogermane (Ge₂H₂Cl₂), or the like. A boron (B) ion source may include, but is not limited to, diborane (B₂H₆), triborane, tetraborane, pentaborane, or the like.

In some implementations, the plurality of source/drain regions 130 may each include a Si layer doped with phosphorus (P). In this case, to form the plurality of source/drain regions 130, the substrate 102 may be in-situ doped with phosphorus (P) ions while supplying a Si source onto the substrate 102. The Si source may be selected from the materials set forth above as examples. A phosphorus (P) ion source may include, but is not limited to, phosphine (PH₃) gas.

Next, the insulating liner 142 may be formed to cover a resulting product in which the plurality of source/drain regions 130 are formed, followed by forming the inter-gate dielectric 144 on the insulating liner 142, and then, a portion of each of the insulating liner 142 and the inter-gate dielectric 144 may be etched, thereby exposing upper surfaces of a plurality of capping layers D126 (see FIGS. 14A and 14B). Next, the dummy gate layer D124 may be exposed by removing the plurality of capping layers D126, and the insulating liner 142 and the inter-gate dielectric 144 may be partially removed such that the upper surface of the inter-gate dielectric 144 and the upper surface of the dummy gate layer D124 are at an approximately equal level.

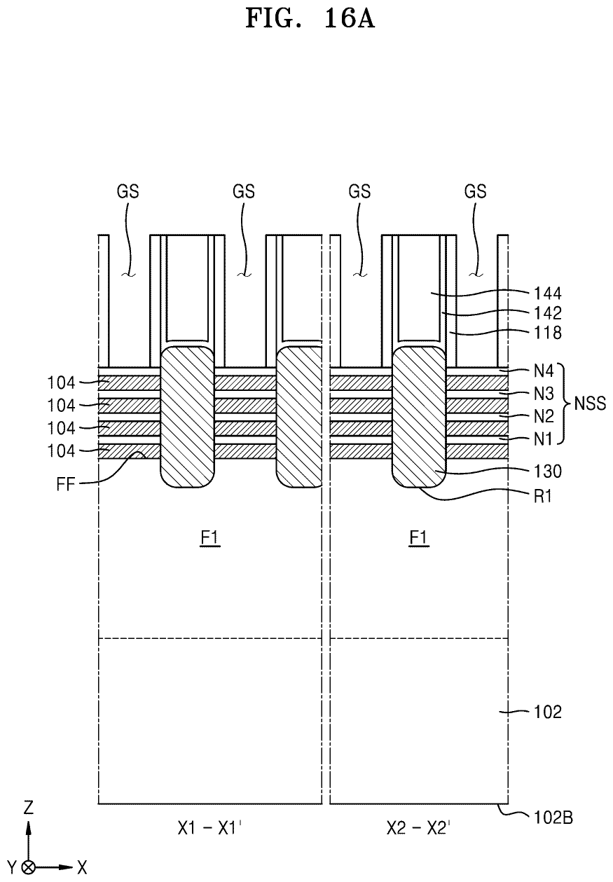

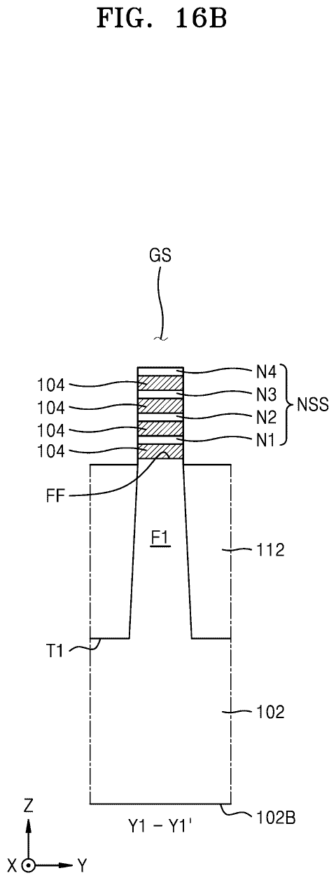

Referring to FIGS. 16A and 16B, the dummy gate layer D124 and the dummy oxide film D122 may be removed from the resulting product of FIGS. 15A, 15B, and 15C, thereby preparing a gate space GS.

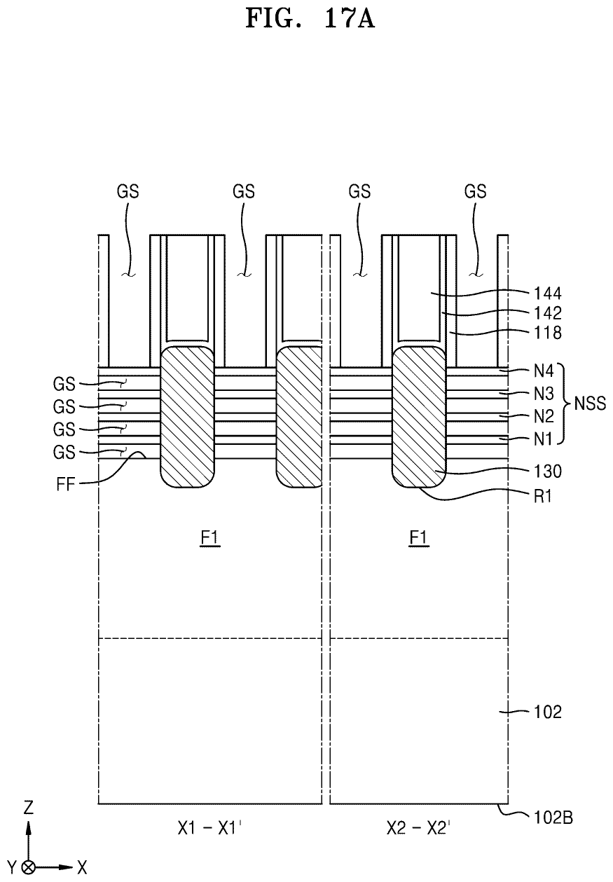

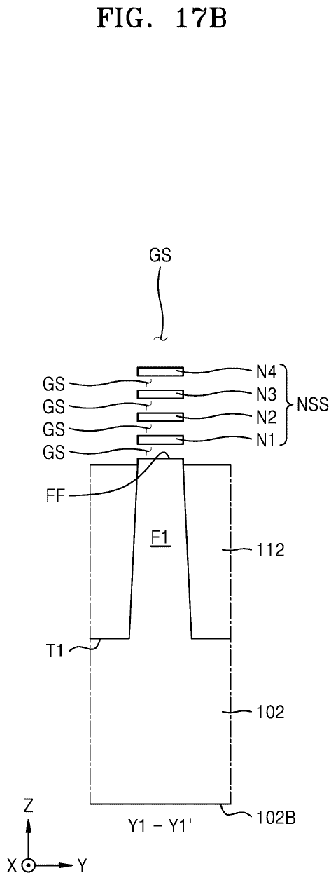

Referring to FIGS. 17A and 17B, the plurality of sacrificial semiconductor layers 104 remaining over the substrate 102 may be selectively removed from the resulting product of FIGS. 16A and 16B, thereby expanding the gate space GS to a space between each of the first to fourth nanosheets N1, N2, N3, and N4 and to a space between the fin top surface FF of the fin-type active region F1 and the first nanosheet N1.

In some implementations, to selectively remove the plurality of sacrificial semiconductor layers 104, a difference in etch selectivity between each of the plurality of sacrificial semiconductor layers 104 and each of the fin-type active region F1 and the first to fourth nanosheets N1, N2, N3, and N4 may be used. To selectively remove the plurality of sacrificial semiconductor layers 104, a liquid-phase or gas-phase etchant may be used. In some implementations, to selectively remove the plurality of sacrificial semiconductor layers 104, a CH₃COOH-based etching solution, for example, an etching solution including a mixture of CH₃COOH, HNO₃, and HF, or an etching solution including a mixture of CH₃COOH, H₂O₂, and HF, may be used, but the present disclosure is not limited thereto.

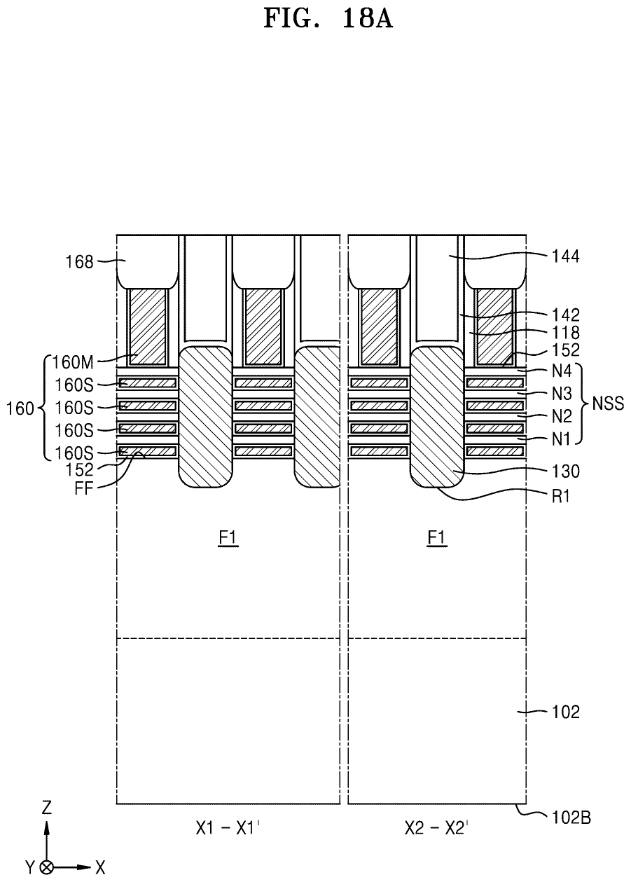

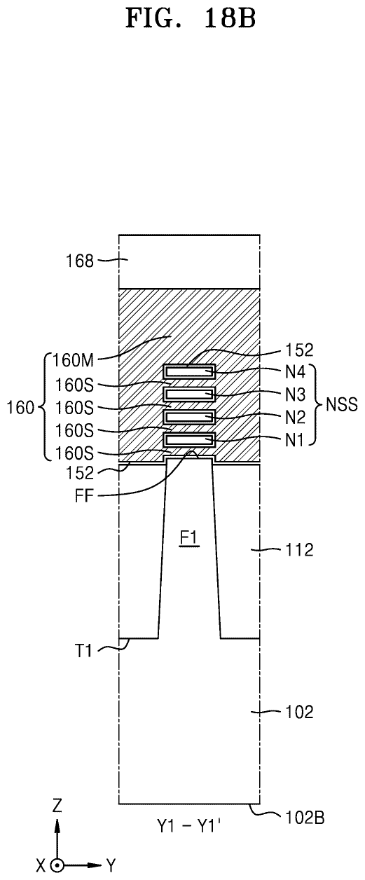

Referring to FIGS. 18A and 18B, in the resulting product of FIGS. 17A and 17B, the gate dielectric film 152 may be formed to cover respective exposed surfaces of the fin-type active region F1 and the first to fourth nanosheets N1, N2, N3, and N4. To form the gate dielectric film 152, an atomic layer deposition (ALD) process may be used.

Next, the gate line 160 may be formed on the gate dielectric film 152 to fill the gate space GS (see FIGS. 17A and 17B). Next, each of the gate line 160, the gate dielectric film 152, and the insulating spacer 118 may be partially removed from the upper surface thereof to reduce the height thereof, and the plurality of capping insulating patterns 168 may each be formed to cover the upper surface of each of the gate line 160, the gate dielectric film 152, and the insulating spacer 118.

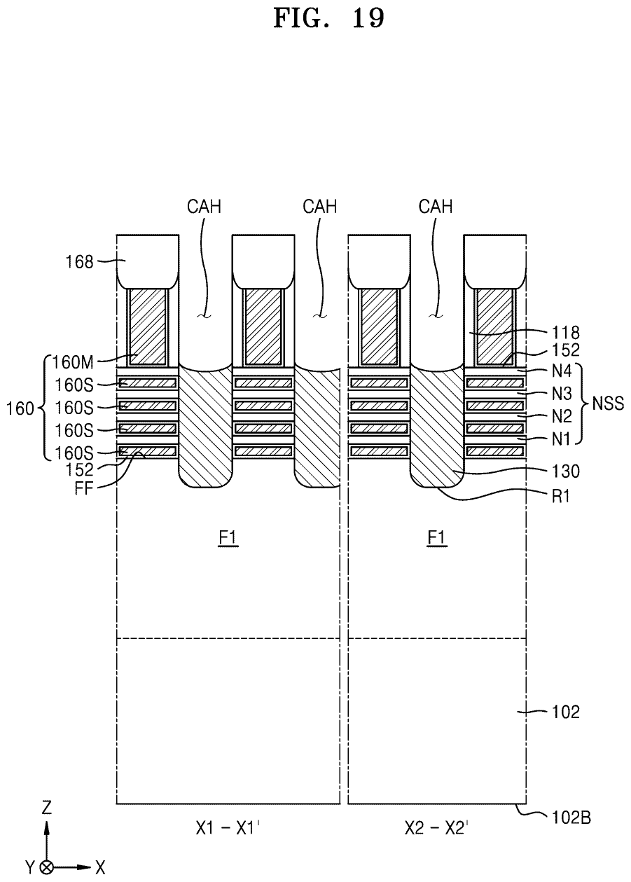

Referring to FIG. 19, a portion of each of the insulating liner 142 and the inter-gate dielectric 144 may be removed from the resulting product of FIGS. 18A and 18B, thereby forming a plurality of source/drain contact holes CAH, which each expose the source/drain region 130. After the plurality of source/drain contact holes CAH are formed, a portion of the frontside surface of the source/drain region 130 may be removed, the portion being exposed by each of the plurality of source/drain contact holes CAH.

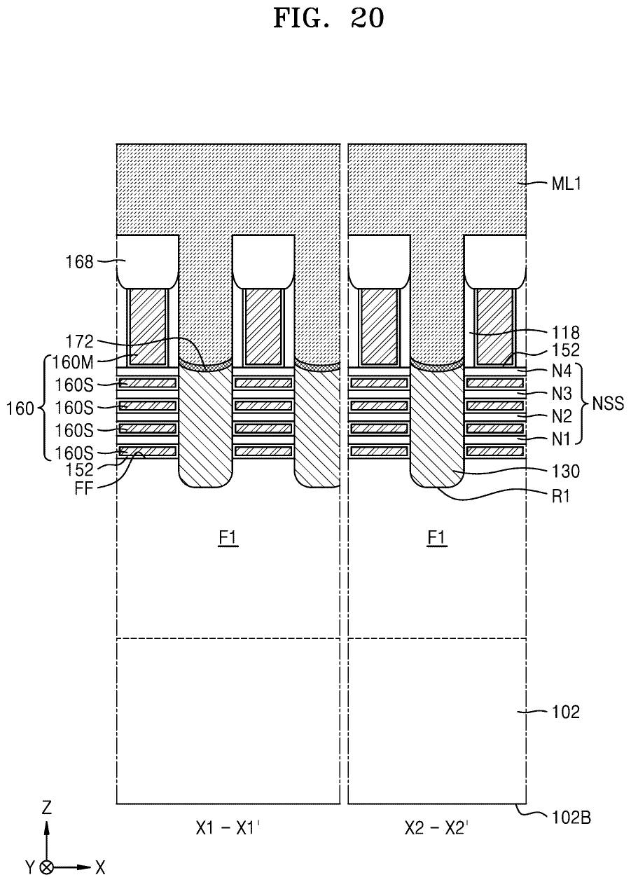

Referring to FIG. 20, in the resulting product of FIG. 19, the metal silicide film 172 may be formed to cover the frontside surface of the source/drain region 130, which is exposed by each of the plurality of source/drain contact holes CAH, and a metal-containing layer ML1 may be formed on the metal silicide film 172 to fill the plurality of source/drain contact holes CAH. The metal-containing layer ML1 may include materials required to form the plurality of source/drain contacts CA (see FIGS. 3A, 3C, and 3E). For example, to form the metal-containing layer ML1, a conductive barrier film may be formed first, and a metal plug may be formed on the conductive barrier film. Regarding detailed configurations of the conductive barrier film and the metal plug, a reference may be made to the description made as to the constituent material of each of the plurality of source/drain contacts CA with reference to FIGS. 3A, 3C, and 3E.

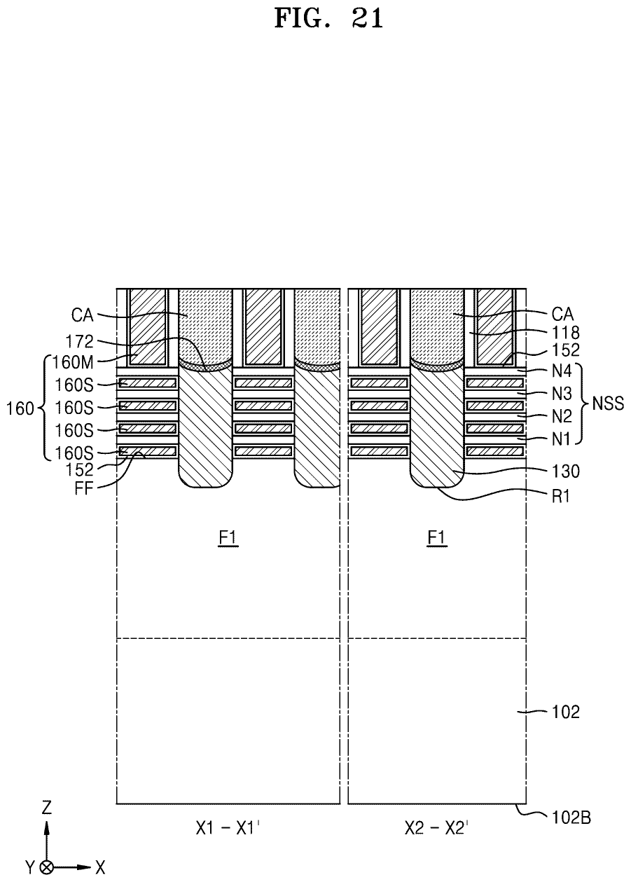

Referring to FIG. 21, the plurality of source/drain contacts CA may be formed from the metal-containing layer ML1 by removing the plurality of capping insulating patterns 168 and a portion of the metal-containing layer ML1 from the resulting product of FIG. 20, and an obtained resulting product may be planarized. While the obtained resulting product is being planarized as described above, a vertical-direction (Z-direction) height of each of the plurality of gate dielectric films 152 and the plurality of insulating spacers 118 may also be reduced.

Referring to FIG. 22, a metal-containing conductive liner 174 may be formed on the planarized upper surface of the resulting product of FIG. 21. A constituent material of the metal-containing conductive liner 174 is the same as the constituent material of each of the first metal-containing conductive liner 174A and the second metal-containing conductive liner 174B described with reference to FIGS. 3A to 3E.

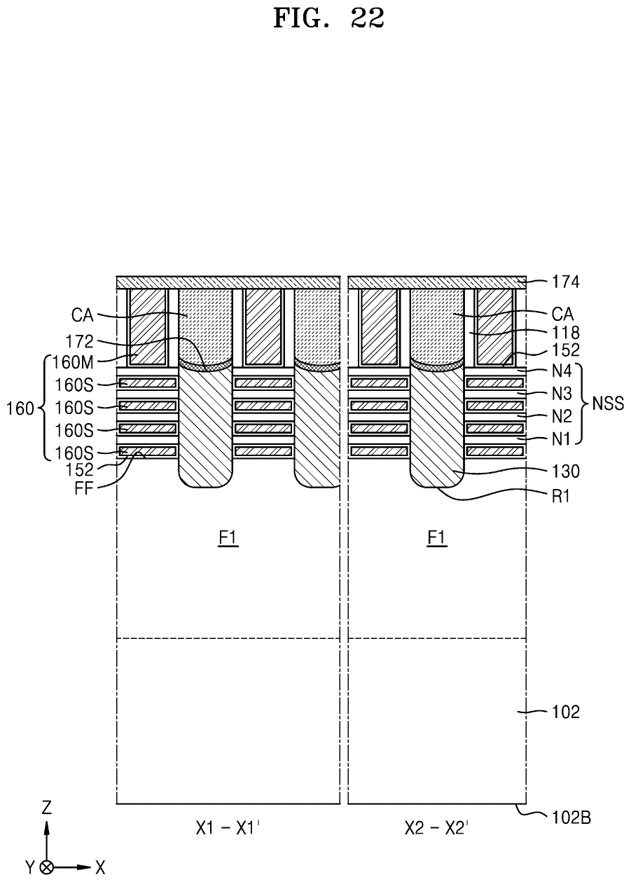

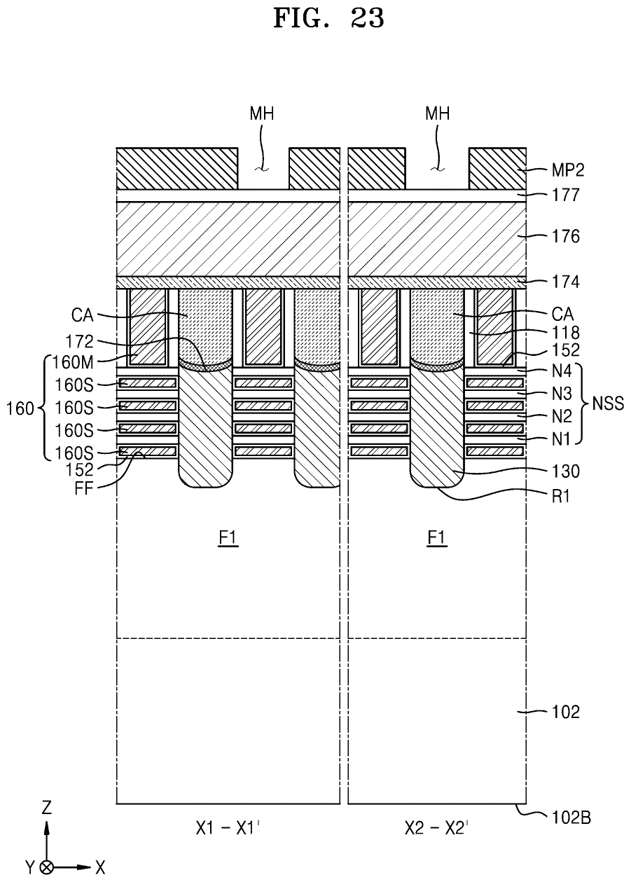

Referring to FIG. 23, a first hardmask film 176 and a second hardmask film 177 may be sequentially formed in the stated order on the metal-containing conductive liner 174, and a mask pattern MP2 may be formed on the second hardmask film 177. In some implementations, the first hardmask film 176 may include a carbon-containing film, such as a spin-on hardmask (SOH) film, and the second hardmask film 177 may include a SiON film. The mask pattern MP2 may include a photoresist pattern. A plurality of openings MH may be formed in the mask pattern MP2. The positions of the plurality of openings MH may respectively correspond to the positions at which the plurality of gate contacts CB and the plurality of source/drain via contacts VA are to be arranged.

Referring to FIG. 24, in the resulting product of FIG. 23, the second hardmask film 177 and the first hardmask film 176 may be sequentially etched in the stated order by using the mask pattern MP2 as an etch mask and using the metal-containing conductive liner 174 as an etch stop film, thereby forming a plurality of openings H1 and H2. The positions of the plurality of openings H1 and H2 may respectively correspond to the positions at which the plurality of gate contacts CB and the plurality of source/drain via contacts VA are to be arranged. After the plurality of openings H1 and H2 are formed, unnecessary films on the second hardmask film 177 may be removed, and the upper surface of the second hardmask film 177 may be exposed.

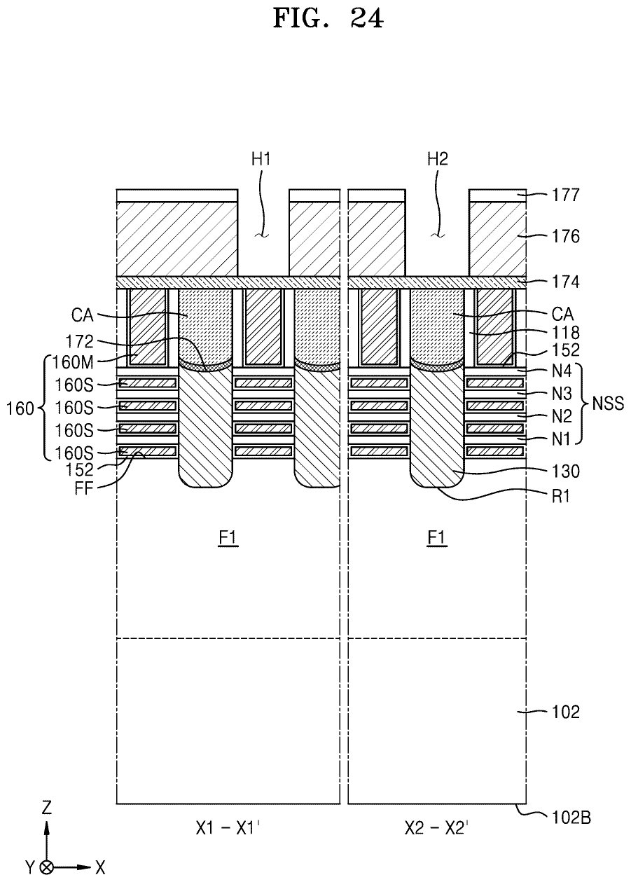

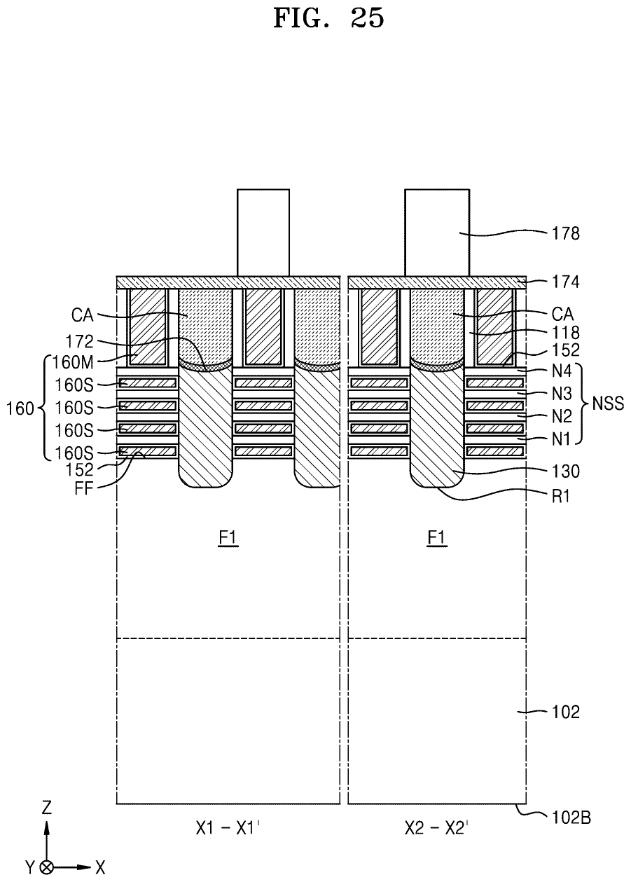

Referring to FIG. 25, in the resulting product of FIG. 24, a plurality of sacrificial mask patterns 178 may be formed to respectively fill the plurality of openings H1 and H2 and to cover the upper surface of the metal-containing conductive liner 174. In some implementations, each of the plurality of sacrificial mask patterns 178 may include, but is not limited to, a silicon oxide film.

Next, the second hardmask film 177 and the first hardmask film 176, which remain around the plurality of sacrificial mask patterns 178, may be removed, thereby exposing the upper surface of the metal-containing conductive liner 174 around each of the plurality of sacrificial mask patterns 178. When the first hardmask film 176 includes an SOH film, to remove the first hardmask film 176 that remains, ashing and strip processes may be used.

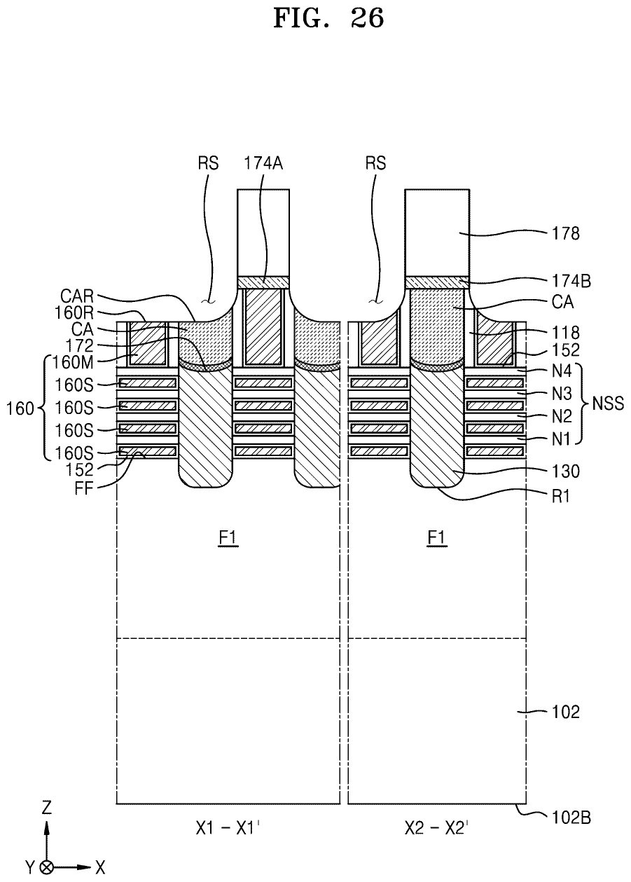

Referring to FIG. 26, in the resulting product of FIG. 25, the metal-containing conductive liner 174 exposed around each of the plurality of sacrificial mask patterns 178 may be etched by using the plurality of sacrificial mask patterns 178 as an etch mask, thereby forming the first metal-containing conductive liner 174A and the second metal-containing conductive liner 174B from the metal-containing conductive liner 174.

A portion of each of the plurality of gate lines 160 and the plurality of source/drain contacts CA, which are exposed around each of the plurality of sacrificial mask patterns 178, may be consecutively removed from a resulting product in which the first metal-containing conductive liner 174A and the second metal-containing conductive liner 174B are formed, thereby reducing the vertical-direction (Z-direction) height of each of the plurality of gate lines 160 and the plurality of source/drain contacts CA. As a result, around each of the plurality of sacrificial mask patterns 178, the gate recess surface 160R may be formed in the upper surface of each of the plurality of gate lines 160 and the contact recess surface CAR may be formed in the upper surface of each of the plurality of source/drain contacts CA. While the portion of each of the plurality of gate lines 160 and the plurality of source/drain contacts CA, which are exposed around each of the plurality of sacrificial mask patterns 178, is being removed, a portion of the gate dielectric film 152 and a portion of the insulating spacer 118, which are adjacent to each of the plurality of gate lines 160 and the plurality of source/drain contacts CA, may also be removed. A recess space RS may be prepared around each of the plurality of sacrificial mask patterns 178, the recess space RS being defined by the gate recess surface 160R of each of the plurality of gate lines 160, the contact recess surface CAR of each of the plurality of source/drain contacts CA, the first metal-containing conductive liner 174A, and the second metal-containing conductive liner 174B.

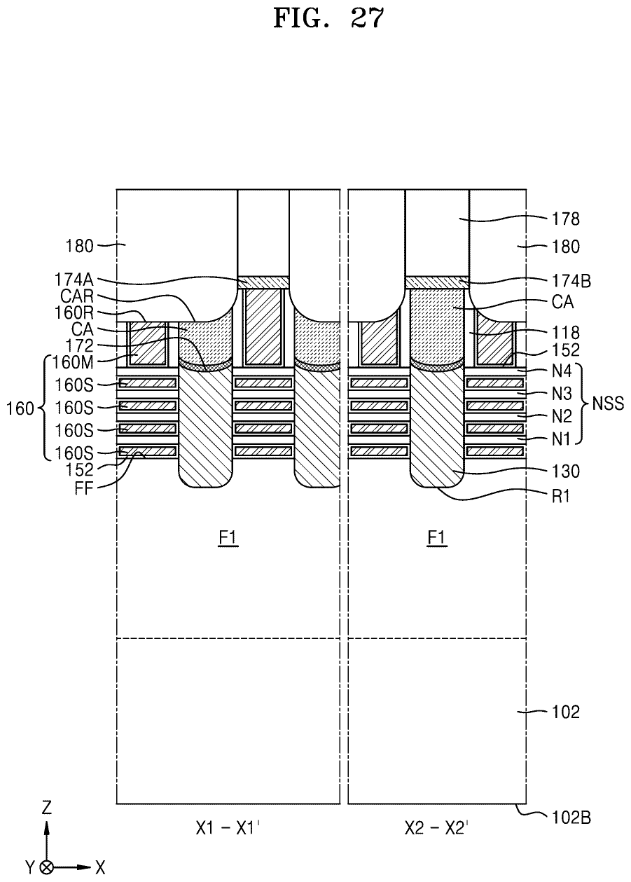

Referring to FIG. 27, in the resulting product of FIG. 26, a capping insulating pattern 180 may be formed to fill the recess space RS. In a resulting product in which the capping insulating pattern 180 is formed, the upper surface of the capping insulating pattern 180 may be coplanar with the upper surface of each of the plurality of sacrificial mask patterns 178.

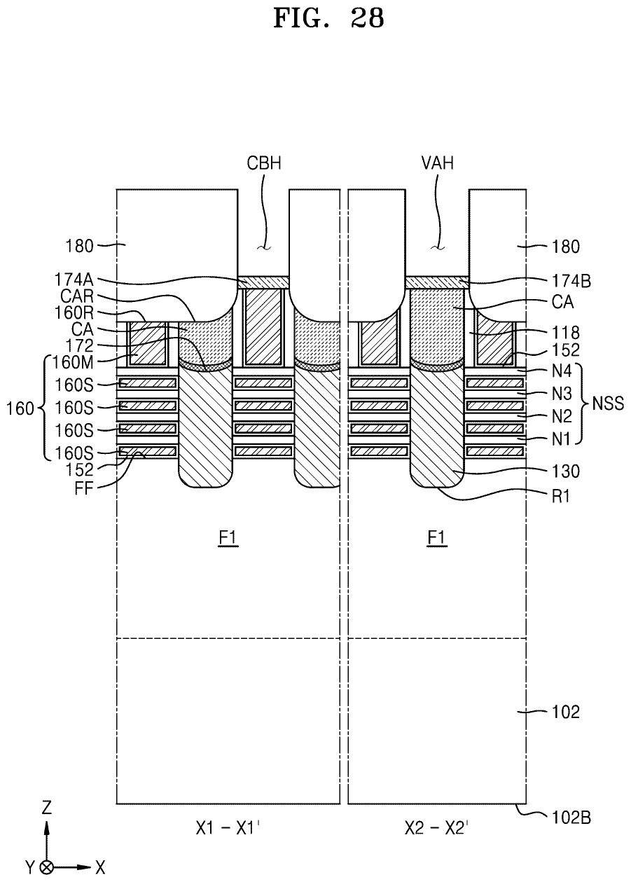

Referring to FIG. 28, by removing the plurality of sacrificial mask patterns 178 from resulting product of FIG. 27, a gate contact hole CBH, which exposes the upper surface of each of the plurality of first metal-containing conductive liners 174A, and a source/drain via contact hole VAH, which exposes the upper surface of each of the plurality of second metal-containing conductive liners 174B, may be formed.

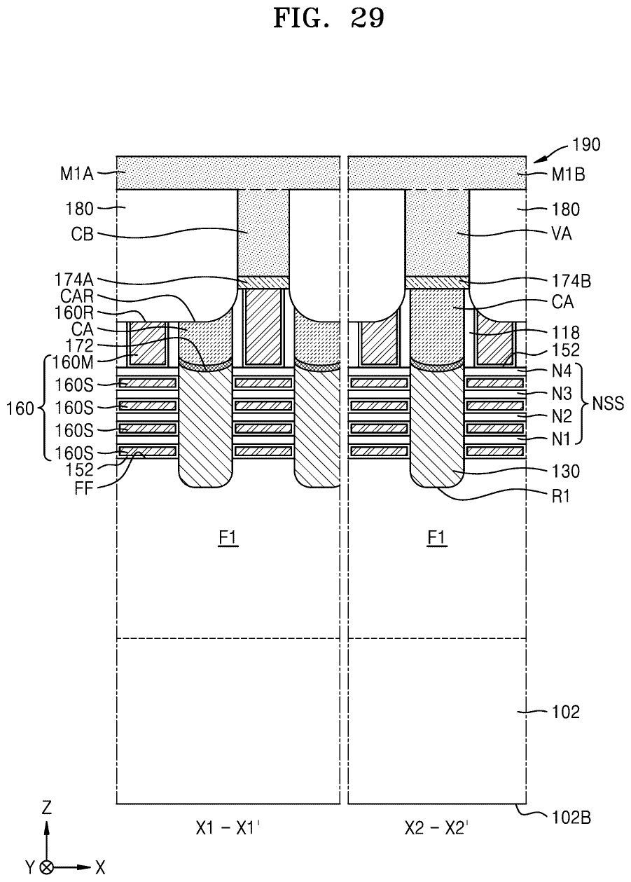

Referring to FIG. 29, in the resulting product of FIG. 28, a conductive film may be formed to fill the gate contact hole CBH and the source/drain via contact hole VAH and to cover the upper surface of the capping insulating pattern 180, and the gate contact CB, the first wiring layer M1A integrally connected to the gate contact CB, the source/drain via contact VA, and the second wiring layer M1B integrally connected to the source/drain via contact VA may be formed by patterning a portion of the conductive film, thereby fabricating the integrated circuit device 100 described with reference to FIGS. 2 and 3A to 3E.

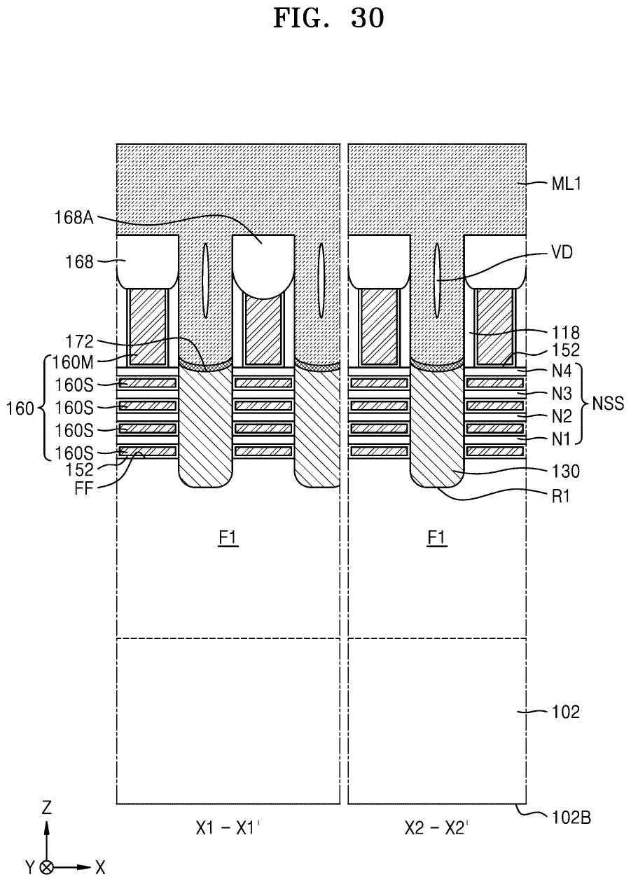

FIGS. 30 to 33 are diagrams respectively illustrating a sequence of processes of a method of fabricating an integrated circuit device, according to some implementations. FIGS. 30 to 33 each illustrate cross-sectional structures respectively corresponding to the cross-section taken along the line X1-X1′ of FIG. 2 and the cross-section taken along the line X2-X2′ of FIG. 2, according to the sequence of processes. An example of a method of fabricating the integrated circuit device 500 shown in FIGS. 7A and 7B is described with reference to FIGS. 30 to 33. In FIGS. 30 to 33, the same reference numerals as in FIGS. 2 to 29 respectively denote the same members, and here, repeated descriptions thereof are omitted.

Referring to FIG. 30, the processes described with reference to FIGS. 11A to 20 may be performed. However, upon performing the process described with reference to FIGS. 18A and 18B, when a portion of each of the plurality of gate lines 160 is removed to form the plurality of capping insulating patterns 168, some of the plurality of gate lines 160 may be removed by as much as a greater thickness than other gate lines 160, and as a result, the lowermost surface of a capping insulating pattern 168A covering each of the gate lines 160 removed by as much as the greater thickness, among the plurality of gate lines 160, may be closer to the substrate 102 than the lowermost surfaces of other capping insulating patterns 168. In addition, when the process described with reference to FIG. 20 is performed, a void VD may be formed inside a portion, which fills each of the plurality of source/drain contact holes CAH (see FIG. 19), of the metal-containing layer ML1.

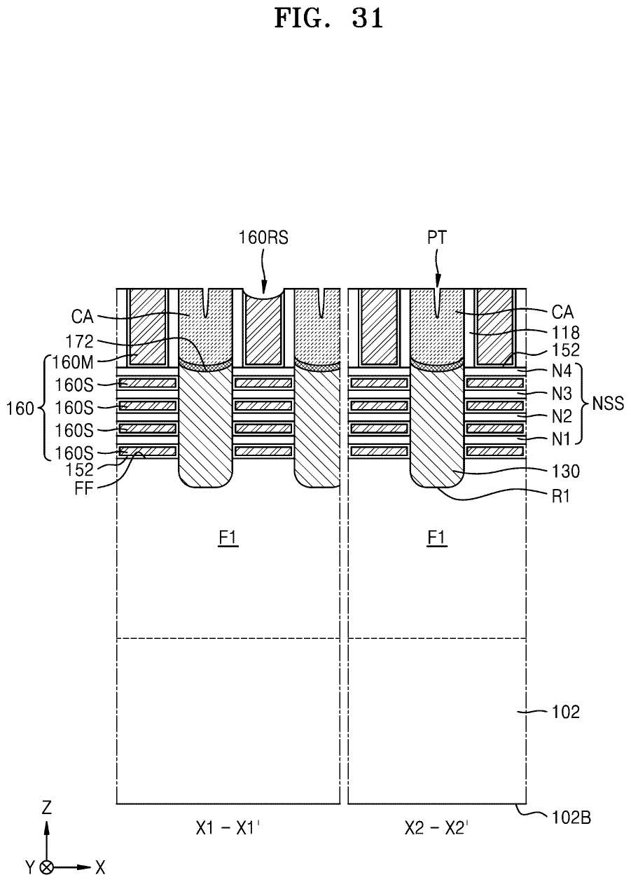

Referring to FIG. 31, in a similar manner to that described with reference to FIG. 21, the plurality of capping insulating patterns 168 and a portion of the metal-containing layer ML1 may be removed from the resulting product of FIG. 30, thereby forming the plurality of source/drain contacts CA from the metal-containing layer ML1, and then, an obtained resulting product may be planarized. Here, the upper surface of the gate line 160 exposed by removing the capping insulating pattern 168A (see FIG. 30) from among the plurality of capping insulating patterns 168 may include a portion lower than those of the other gate lines 160, and a gate recess space 160RS may be formed on the upper surface of the gate line 160 exposed by removing the capping insulating pattern 168A (see FIG. 30). In addition, a local pit PT due to the void VD (see FIG. 30) may be formed in the upper surface of each of the plurality of source/drain contacts CA.

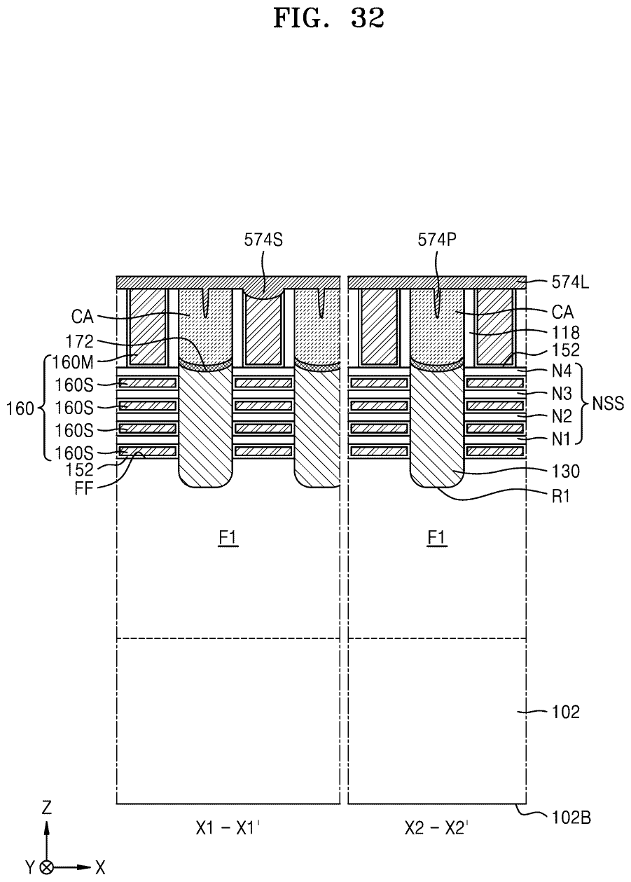

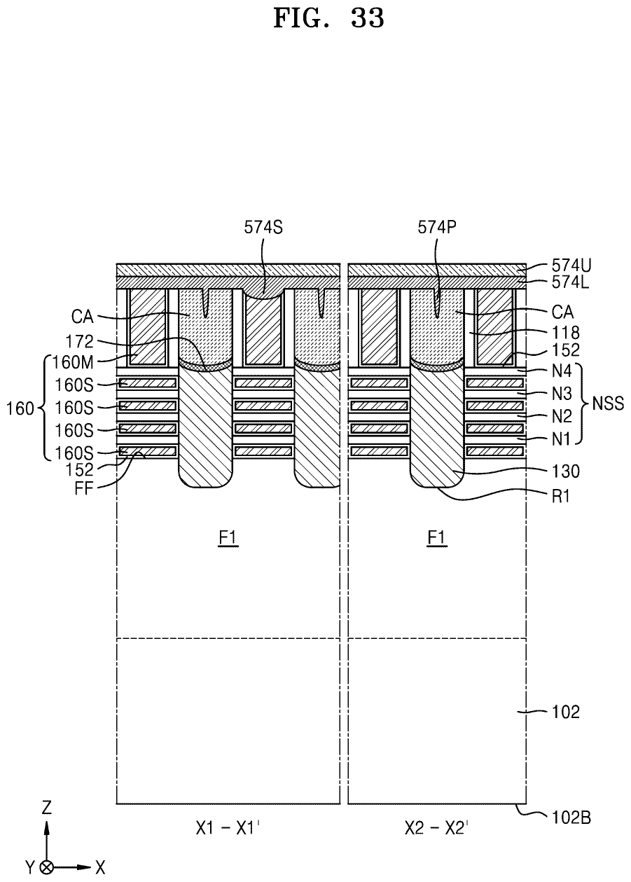

Referring to FIG. 32, in a similar manner to that described with reference to FIG. 22, a lower conductive liner 574L may be formed on the resulting product of FIG. 31. The lower conductive liner 574L may include a sagging portion 574S, which fills the gate recess space 160RS, and a protruding portion 574P, which fills the local pit PT. A constituent material of the lower conductive liner 574L is the same as the constituent material of each of the first lower conductive liner 574LA and the second lower conductive liner 574LB described with reference to FIGS. 7A and 7B.

Referring to FIG. 33, an upper conductive liner 574U may be formed on the lower conductive liner 574L. A constituent material of the upper conductive liner 574U is the same as the constituent material of each of the first upper conductive liner 574UA and the second upper conductive liner 574UB described with reference to FIGS. 7A and 7B.

Next, the processes described with reference to FIGS. 23 to 29 may be performed on the resulting product of FIG. 33, thereby fabricating the integrated circuit device 500 described with reference to FIGS. 7A and 7B.

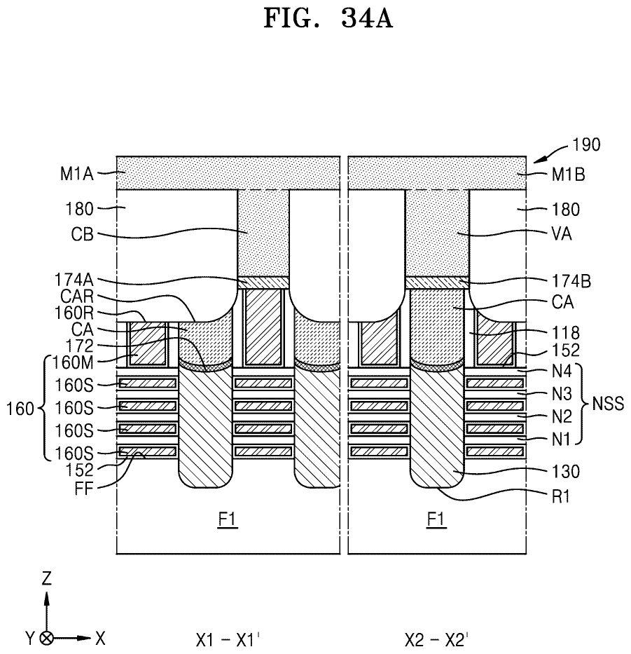

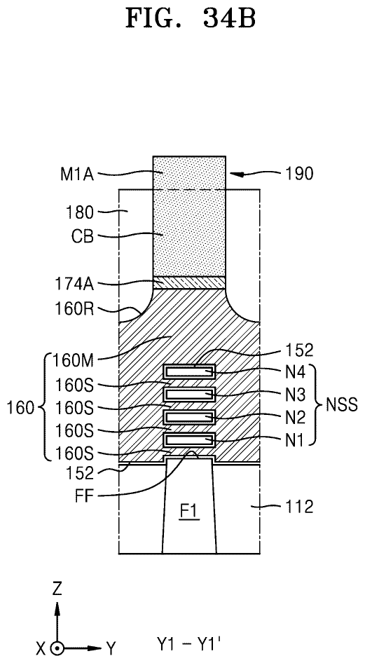

FIGS. 34A to 40 are diagrams respectively illustrating a sequence of processes of a method of fabricating an integrated circuit device, according to some implementations. More specifically, FIGS. 34A, 35A, 36A, and 37 to 40 are cross-sectional views each illustrating cross-sectional structures of regions respectively corresponding to the cross-section taken along the line X1-X1′ of FIG. 2 and the cross-section taken along the line X2-X2′ of FIG. 2, according to the sequence of processes. FIGS. 34B, 35B, and 36B are cross-sectional views each illustrating a cross-sectional structure of a region corresponding to the cross-section taken along the line Y1-Y1′ of FIG. 2, according to the sequence of processes. An example of a method of fabricating the integrated circuit device 700 shown in FIG. 9 is described with reference to FIGS. 34A to 40. In FIGS. 34A to 40, the same reference numerals as in FIGS. 2 to 33 respectively denote the same members, and here, repeated descriptions thereof are omitted.

Referring to FIGS. 34A and 34B, in the structure described with reference to FIGS. 2 and 3A to 3E, the plurality of fin-type active regions F1 and the device isolation film 112 may be exposed by removing the substrate 102 from the backside surface 102B of the substrate 102, and a portion of each of the device isolation film 112 and the plurality of fin-type active regions F1, which are exposed, may be further removed, thereby reducing the vertical-direction (Z-direction) thickness of each of the device isolation film 112 and the plurality of fin-type active regions F1.

In some implementations, to remove the substrate 102 and to remove a portion of each of the device isolation film 112 and the plurality of fin-type active regions F1, at least one process selected from a mechanical grinding process, a chemical mechanical polishing (CMP) process, a wet etching process, and any combination thereof may be used.

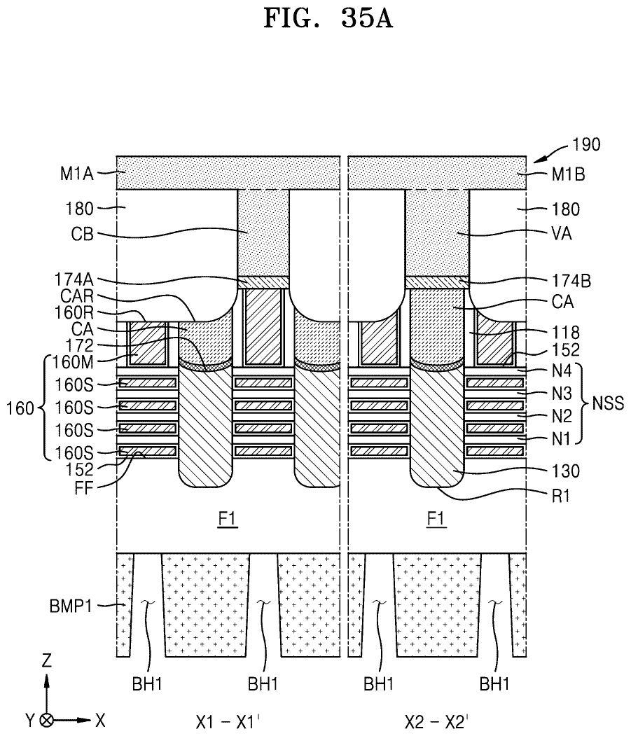

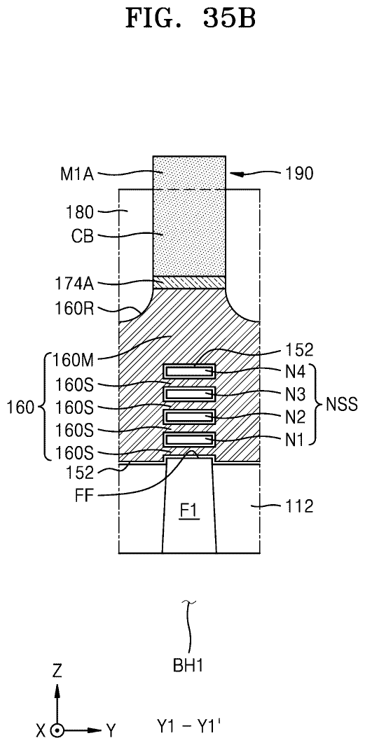

Referring to FIGS. 35A and 35B, in the resulting product of FIGS. 34A and 34B, a first backside mask pattern BMP1 may be formed on a backside surface at which the plurality of fin-type active regions F1 and the device isolation film 112 are exposed. The first backside mask pattern BMP1 may have a plurality of line-shaped openings BH1 extending lengthwise in the second horizontal direction (the Y direction). Each of the device isolation film 112 and the plurality of fin-type active regions F1 may be partially exposed by the plurality of line-shaped openings BH1 of the first backside mask pattern BMP1. In some implementations, the first backside mask pattern BMP1 may include, but is not limited to, an SOH material.

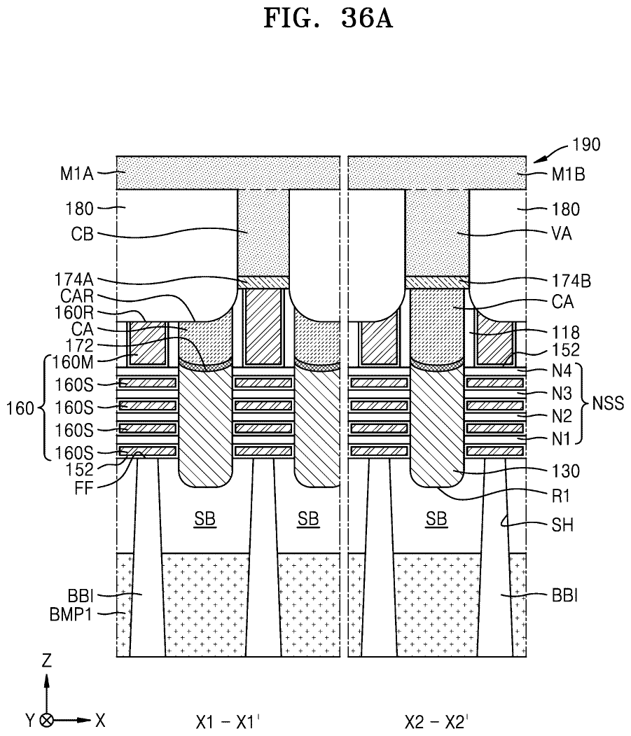

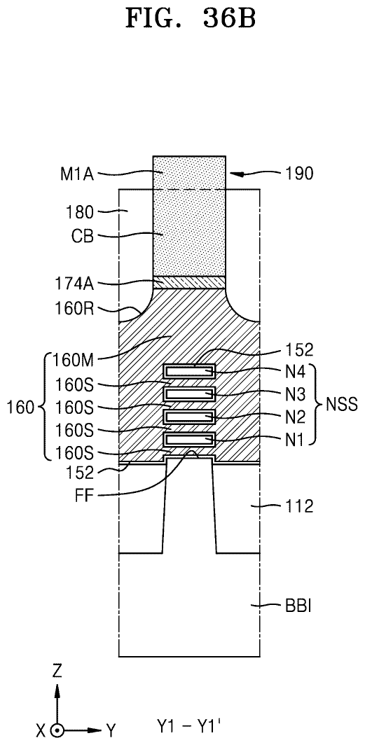

Referring to FIGS. 36A and 36B, in the resulting product of FIGS. 35A and 35B, the plurality of fin-type active regions F1 may be selectively etched by using the first backside mask pattern BMP1 as an etch mask, thereby forming a plurality of vertical holes SH, which each expose the gate dielectric film 152. As the plurality of vertical holes SH are formed, each of the plurality of fin-type active regions F1 may be divided into a plurality of semiconductor blocks SB.

Next, a plurality of backside bulk insulating films BBI may be formed to respectively fill the plurality of vertical holes SH and the plurality of line-shaped openings BH1. In some implementations, to form the plurality of backside bulk insulating films BBI, an ALD process or a CVD process may be used, but the present disclosure is not limited thereto.

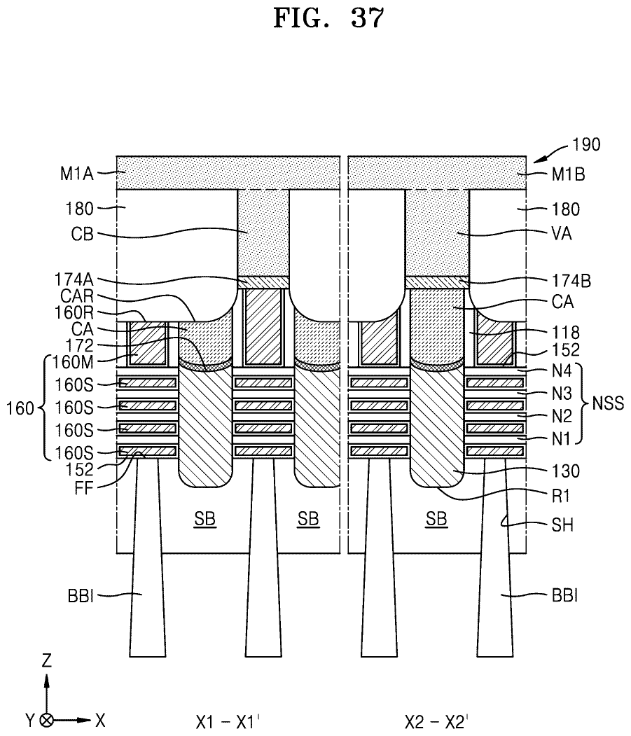

Referring to FIG. 37, the first backside mask pattern BMP1 may be removed from the resulting product of FIGS. 36A and 36B. When the first backside mask pattern BMP1 includes an SOH material, to remove the first backside mask pattern BMP1, ashing and strip processes may be used.

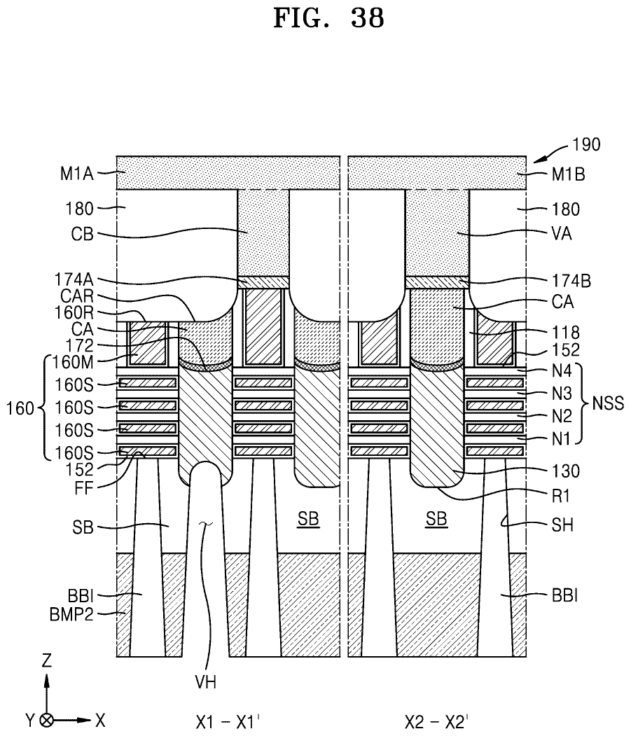

Referring to FIG. 38, a planarized hardmask film may be formed by coating an SOH material on a resulting product having undergone the process described with reference to FIG. 37, and the hardmask film may be patterned, thereby forming a second backside mask pattern BMP2, which has a hole exposing a semiconductor block SB. Next, the semiconductor block SB may be etched by using the second backside mask pattern BMP2 as an etch mask, thereby forming a via hole VH, which exposes the backside surface of the source/drain region 130. While the via hole VH is being formed, the source/drain region 130 may be partially etched, and thus, the via hole VH may extend to the inside of the source/drain region 130.

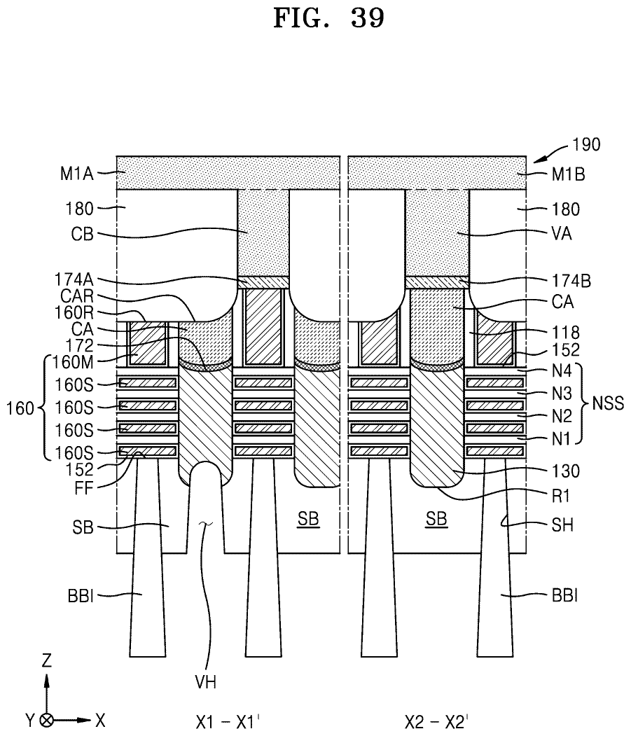

Referring to FIG. 39, the second backside mask pattern BMP2 may be removed from the resulting product of FIG. 38. When the second backside mask pattern BMP2 includes an SOH material, to remove the second backside mask pattern BMP2, ashing and strip processes may be used.

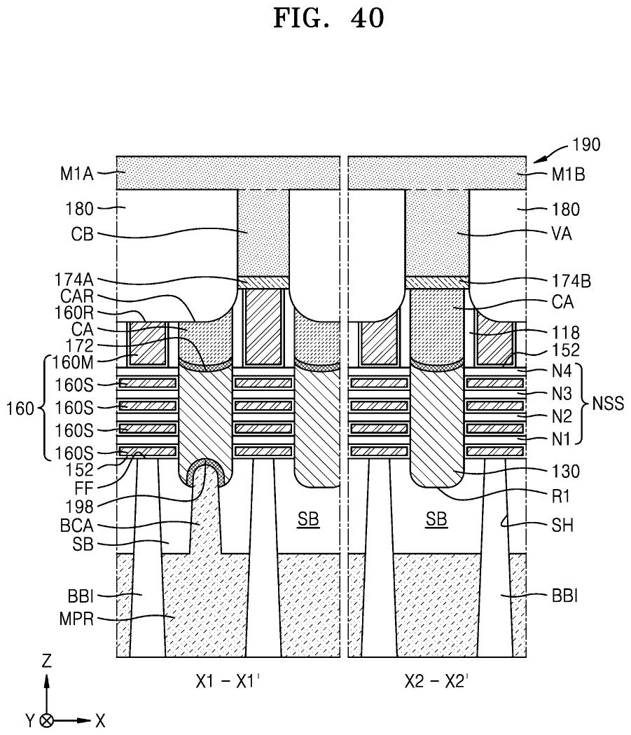

Referring to FIG. 40, in the resulting product of FIG. 39, the backside source/drain contact BCA and the backside power rail MPR may be formed by filling the via hole VH and a space between each of the backside bulk insulating films BBI with a conductive material, thereby fabricating the integrated circuit device 700 shown in FIG. 9.

Heretofore, although the examples of the methods of fabricating the integrated circuit device 100 shown in FIGS. 2 and 3A to 3E, the integrated circuit device 500 shown in FIGS. 7A and 7B, and the integrated circuit device 700 shown in FIG. 9 have been described with reference to FIGS. 11A to 40, it will be understood by those of ordinary skill in the art that, by making various modifications and changes to the examples described with reference to FIGS. 11A to 40 without departing from the spirit and scope of the present disclosure, the integrated circuit device 200 shown in FIGS. 4A and 4B, the integrated circuit devices 300 and 400 respectively shown in FIGS. 5 and 6, the integrated circuit device 600 shown in FIG. 8, and integrated circuit devices having various structures modified and changed therefrom may be fabricated.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. An integrated circuit device comprising:
a channel region;
a gate line surrounding the channel region, the gate line having a first upper surface that extends at a first vertical level, the first vertical level being apart from a reference vertical level of an uppermost surface of the channel region in a vertical direction;
a source/drain region contacting the channel region;
a source/drain contact over the source/drain region, the source/drain contact being connected to the source/drain region and having a second upper surface that extends at the first vertical level;
a gate contact at a second vertical level, the gate contact being connected to the gate line, the second vertical level being higher than the first vertical level;
a source/drain via contact at the second vertical level, the source/drain via contact being connected to the source/drain contact; and
a metal-containing conductive liner between the first vertical level and the second vertical level, the metal-containing conductive liner contacting one selected from the first upper surface of the gate line and the second upper surface of the source/drain contact, the metal-containing conductive liner having a width in a horizontal direction that is greater than a width of the selected one in the horizontal direction.

2. The integrated circuit device of claim 1, wherein the metal-containing conductive liner is between the first upper surface of the gate line and a first lower surface of the gate contact, the first lower surface facing the gate line, and
wherein the gate contact has a width in the horizontal direction that is greater than a width of the gate line in the horizontal direction.

3. The integrated circuit device of claim 2, comprising a back-end-of-line (BEOL) structure on the gate contact and the source/drain via contact,
wherein the BEOL structure comprises a first wiring layer, the gate contact being between the first wiring layer and the metal-containing conductive liner in the vertical direction, the first wiring layer being connected to the gate contact.

4. The integrated circuit device of claim 1, wherein the metal-containing conductive liner is between the second upper surface of the source/drain contact and a second lower surface of the source/drain via contact, the second lower surface facing the source/drain contact, and
wherein the source/drain via contact has a width in the horizontal direction that is greater than a width of the source/drain contact in the horizontal direction.

5. The integrated circuit device of claim 4, comprising a back-end-of-line (BEOL) structure on the gate contact and the source/drain via contact,
wherein the BEOL structure comprises a second wiring layer, the source/drain via contact being between the second wiring layer and the metal-containing conductive liner in the vertical direction, the second wiring layer being connected to the source/drain via contact.

6. The integrated circuit device of claim 1, wherein the metal-containing conductive liner comprises:
a single-film structure comprising a conductive metal nitride film; or
a multi-film structure comprising a conductive metal nitride film and a metal film.

7. The integrated circuit device of claim 1, wherein the metal-containing conductive liner is in contact with the first upper surface of the gate line, the metal-containing conductive liner having the width in the horizontal direction that is greater than a width of the first upper surface of the gate line in the horizontal direction,
wherein the first upper surface of the gate line has a concave shape, and
wherein the metal-containing conductive liner comprises:
a liner body portion protruding beyond the first upper surface of the gate line in the horizontal direction; and
a sagging portion connected to the liner body portion, the sagging portion protruding from the liner body portion toward the gate line, the sagging portion having a convex shape.

8. The integrated circuit device of claim 7, comprising an insulating spacer covering a sidewall of the gate line,
wherein the metal-containing conductive liner covers an upper surface of the insulating spacer.

9. The integrated circuit device of claim 1, wherein the metal-containing conductive liner is in contact with the second upper surface of the source/drain contact, the metal-containing conductive liner having the width in the horizontal direction that is greater than a width of the second upper surface of the source/drain contact,
wherein the second upper surface of the source/drain contact has a dent portion, the dent portion having a concave shape, and
wherein the metal-containing conductive liner comprises:
a liner body portion protruding beyond the second upper surface of the source/drain contact in the horizontal direction; and
a protruding portion connected to the liner body portion, the protruding portion protruding from the liner body portion toward the source/drain contact, the protruding portion being disposed at the dent portion of the source/drain contact.

10. The integrated circuit device of claim 9, comprising an insulating spacer covering a sidewall of the source/drain contact,
wherein the metal-containing conductive liner covers an upper surface of the insulating spacer.

11. An integrated circuit device comprising:
a plurality of channel regions apart from each other in a first horizontal direction;
a plurality of gate lines respectively surrounding the plurality of channel regions, each of the plurality of gate lines extending in a second horizontal direction that is perpendicular to the first horizontal direction, each of the plurality of gate lines having a first upper surface extending at a first vertical level that is apart from a reference vertical level of an uppermost surface of each of the plurality of channel regions in a vertical direction;
a plurality of source/drain regions each between corresponding adjacent gate lines of the plurality of gate lines;
a plurality of source/drain contacts each being connected to a respective source/drain region of the plurality of source/drain regions, each of the plurality of source/drain contacts having a second upper surface extending at the first vertical level;
a plurality of gate contacts at a second vertical level and each being connected to a respective gate line of the plurality of gate lines, the second vertical level being higher than the first vertical level;
a plurality of source/drain via contacts at the second vertical level and each being connected to a respective source/drain contact of the plurality of source/drain contacts;
a plurality of insulating spacers each between a corresponding gate line of the plurality of gate lines and a corresponding source/drain contact of the plurality of source/drain contacts; and
a first metal-containing conductive liner comprising a first portion in contact with the first upper surface of a first gate line of the plurality of gate lines, and a second portion covering an upper surface of a first insulating spacer of the plurality of insulating spacers, the upper surface of the first insulating spacer being adjacent to the first upper surface of the first gate line, the first metal-containing conductive liner having a width in the first horizontal direction that is greater than a width of the first upper surface of the first gate line in the first horizontal direction,
wherein the first metal-containing conductive liner is between a first gate contact of the plurality of gate contacts and the first gate line, and the first gate contact is connected to the first gate line through the first metal-containing conductive liner.

12. The integrated circuit device of claim 11, wherein the first gate contact has a width in the first horizontal direction that is greater than the width of the first upper surface of the first gate line in the first horizontal direction.

13. The integrated circuit device of claim 11, comprising a second metal-containing conductive liner comprising:
a first portion in contact with the second upper surface of a first source/drain contact of the plurality of source/drain contacts, and
a second portion covering an upper surface of a second insulating spacer of the plurality of insulating spacers, the upper surface of the second insulating spacer being adjacent to the second upper surface of the first source/drain contact, the second metal-containing conductive liner having a width in the first horizontal direction that is greater than a width of the second upper surface of the first source/drain contact in the first horizontal direction,
wherein the second metal-containing conductive liner is between a first source/drain via contact of the plurality of source/drain via contacts and the first source/drain contact in the vertical direction, and the first source/drain via contact is connected to the first source/drain contact through the second metal-containing conductive liner.

14. The integrated circuit device of claim 13, wherein the first source/drain via contact has a width in the first horizontal direction that is greater than the width of the second upper surface of the first source/drain contact.

15. The integrated circuit device of claim 13, wherein the first metal-containing conductive liner and the second metal-containing conductive liner are at a same vertical level between the first vertical level and the second vertical level, and wherein the first metal-containing conductive liner and the second metal-containing conductive liner comprise a same metal element.

16. The integrated circuit device of claim 13, comprising a back-end-of-line (BEOL) structure on the plurality of gate contacts and the plurality of source/drain via contacts,
wherein the BEOL structure comprises:
a first wiring layer, the first gate contact being between the first wiring layer and the first metal-containing conductive liner in the vertical direction, the first wiring layer being connected to the first gate contact; and
a second wiring layer, the first source/drain via contact being between the second wiring layer and the second metal-containing conductive liner in the vertical direction, the second wiring layer being connected to the first source/drain via contact.

17. The integrated circuit device of claim 13, wherein the first upper surface of the first gate line has a concave shape,
wherein the first metal-containing conductive liner comprises
a first liner body portion protruding beyond the first upper surface of the first gate line in the first horizontal direction, and
a sagging portion connected to the first liner body portion, the sagging portion protruding from the first liner body portion toward the first gate line, the sagging portion having a convex shape,
wherein the second upper surface of the first source/drain contact has a dent portion that has a concave shape, and
wherein the second metal-containing conductive liner comprises
a second liner body portion protruding beyond the second upper surface of the first source/drain contact in the first horizontal direction, and
a protruding portion connected to the second liner body portion, the protruding portion protruding from the second liner body portion toward the first source/drain contact, the protruding portion being disposed at the dent portion of the first source/drain contact.

18. An integrated circuit device comprising:
a plurality of nanosheet stacks each comprising a plurality of nanosheets overlapping each other in a vertical direction;
a plurality of gate lines each surrounding the plurality of nanosheets of a respective nanosheet stack of the plurality of nanosheet stacks, each of the plurality of gate lines having a first upper surface extending at a first vertical level, the first vertical level being apart from a reference vertical level of an uppermost surface of the respective nanosheet stack in the vertical direction;
a plurality of source/drain regions each between corresponding adjacent gate lines of the plurality of gate lines;
a plurality of source/drain contacts each connected to a respective source/drain region of the plurality of source/drain regions, each of the plurality of source/drain contacts having a second upper surface extending at the first vertical level;
a plurality of gate contacts at a second vertical level and each being connected to a respective gate line of the plurality of gate lines, the second vertical level being higher than the first vertical level;
a plurality of source/drain via contacts at the second vertical level and each being connected to a respective source/drain contact of the plurality of source/drain contacts;
a plurality of insulating spacers each between a corresponding gate line of the plurality of gate lines and a corresponding source/drain contact of the plurality of source/drain contacts;
a first metal-containing conductive liner comprising a first portion in contact with the first upper surface of a first gate line of the plurality of gate lines, and a second portion covering an upper surface of a first insulating spacer of the plurality of insulating spacers, the upper surface of the first insulating spacer being adjacent to the first upper surface of the first gate line, the first metal-containing conductive liner having a width in a horizontal direction that is greater than a width of the first upper surface of the first gate line in the horizontal direction; and
a second metal-containing conductive liner comprising a first portion in contact with the second upper surface of a first source/drain contact of the plurality of source/drain contacts, and a second portion covering an upper surface of a second insulating spacer of the plurality of insulating spacers, the upper surface of the second insulating spacer being adjacent to the second upper surface of the first source/drain contact, the second metal-containing conductive liner having a width in the horizontal direction that is greater than a width of the second upper surface of the first source/drain contact in the horizontal direction.

19. The integrated circuit device of claim 18, comprising a back-end-of-line (BEOL) structure on the plurality of gate contacts and the plurality of source/drain via contacts,
wherein the BEOL structure comprises:
a first wiring layer, a first gate contact of the plurality of gate contacts being between the first wiring layer and the first metal-containing conductive liner in the vertical direction, the first wiring layer being connected to the first gate contact; and
a second wiring layer, a first source/drain via contact of the plurality of source/drain via contacts being between the second wiring layer and the second metal-containing conductive liner in the vertical direction, the second wiring layer being connected to the first source/drain via contact.

20. The integrated circuit device of claim 18, wherein the first metal-containing conductive liner and the second metal-containing conductive liner are at a same vertical level between the first vertical level and the second vertical level, and
wherein the first metal-containing conductive liner and the second metal-containing conductive liner comprise a same material including at least one of Ti, TiN, Ta, TaN, Mo, W, Ru, Nb, Ni, Co, Pt, Yb, Tb, Dy, Er, or Pd.
